(19) United States
(12) Patent Application Publication
(10) Pub. No.: US 2013/0043770 A1
(43) Pub. Date: Feb. 21, 2013

(54) PIEZOELECTRIC VIBRATING PIECE AND PIEZOELECTRIC DEVICE

(71) Applicant: SHUICHI MIZUSAWA, SAITAMA (JP)

(72) Inventor: SHUICHI MIZUSAWA, SAITAMA (JP)

(73) Assignee: NIHON DEMPA KOGYO CO., LTD., TOKYO (JP)

(21) Appl. No.: 13/569,184

(22) Filed: Aug. 8, 2012

(30) Foreign Application Priority Data
Aug. 17, 2011 (JP) 2011-178365
Aug. 23, 2011 (JP) 2011-181216

(51) Int. Cl. H01L 41/053

(52) U.S. Cl. 310/344; 310/348

(57) ABSTRACT

A piezoelectric vibrating piece includes a vibrator in a rectangular shape, a framing portion, and one connecting portion. The vibrator includes a first side and a pair of second sides. The first side extends in a first direction. The second sides extend in a second direction perpendicular to the first direction. The framing portion surrounds the vibrator across a void. The one connecting portion connects the first side of the vibrator and the framing portion together. The one connecting portion has a predetermined width in the first direction. The one connecting portion extends in the second direction.

### CROSS REFERENCE TO RELATED APPLICATIONS

This application claims the priority benefit of Japan application serial no. 2011-178365, filed on Aug. 17, 2011, and Japan application serial no. 2011-181216, filed on August 23. The entirety of each of the above-mentioned patent applications is hereby incorporated by reference herein and made a part of this specification.

### TECHNICAL FIELD

This disclosure pertains to piezoelectric vibrating pieces or piezoelectric devices that reduce influence of stresses on vibrators.

### DESCRIPTION OF THE RELATED ART

A known piezoelectric vibrating piece includes a vibrator, which vibrates at a predetermined vibration frequency, and a framing portion, which surrounds a peripheral area of the vibrator. The piezoelectric vibrating piece makes a piezoelectric device with a lid plate and a base plate, which are bonded on front and back sides of its framing portion. The piezoelectric device is used being mounted on a printed circuit board or the like. The piezoelectric device may undergo stress on the printed circuit board. The stress on the piezoelectric device affects the piezoelectric vibrating piece, thus changing a characteristic of the vibration frequency of the vibrator.

For example, Japanese Unexamined Patent Application Publication No. 2011-66779 discloses a method that prevents a vibrator from being subjected to a stress, which affects on vibration frequency of the vibrator. This method separates the vibrator and a bonding portion in the piezoelectric vibrating piece from each other with a notch, thus preventing the stress from transferring to the vibrator. This reduces change in characteristic of vibration frequency of the piezoelectric vibrating piece.

However, even the method in Japanese Unexamined Patent Application Publication No. 2011-66779 does not sufficiently reduce the change in characteristic vibration frequency of the piezoelectric vibrating piece. The piezoelectric vibrating piece in this publication does not have a framing portion. It is preferred that the piezoelectric vibrating piece further prevent a stress on the vibrator so as to reduce the change in characteristic of the vibration frequency.

It is an object of the present invention to provide a piezoelectric vibrating piece and a piezoelectric device that reduce influence of stress on a vibrator where a framing portion and the vibrator are connected with one connecting portion.

### SUMMARY

One aspect of the present invention is directed to a piezoelectric vibrating piece. The piezoelectric vibrating piece includes a vibrator in a rectangular shape, a framing portion, and one connecting portion. The vibrator includes a first side and a pair of second sides. The first side extends in a first direction. The second sides extend in a second direction perpendicular to the first direction. The framing portion surrounds the vibrator across a void. The one connecting portion connects the first side of the vibrator and the framing portion together. The one connecting portion has a predetermined width in the first direction. The one connecting portion extends in the second direction.

The piezoelectric vibrating piece of the present invention connects the vibrator and the framing portion with the one connecting portion, thus reducing influence of the stress on the vibrator.

### BRIEF DESCRIPTION OF THE DRAWINGS

FIG. 1 is an exploded perspective view of a piezoelectric device 100.

FIG. 2A is a cross-sectional view taken along the line A-A of FIG. 1.

FIG. 2B is a plan view of a piezoelectric vibrating piece 130.

FIG. 3A is a plan view of a piezoelectric vibrating piece 130 without electrodes.

FIG. 3B is a cross-sectional view taken along the line B-B of FIG. 2B.

FIG. 4A is a simulation result of a piezoelectric vibrating piece that includes a connecting portion 133 with a width WR of 0.32 mm.

FIG. 4B is a simulation result of a piezoelectric vibrating piece that includes a connecting portion 133 with a width WR of 0.35 mm.

FIG. 4C is a simulation result of a piezoelectric vibrating piece that includes a connecting portion 133 with a width WR of 0.45 mm.

FIG. 4D is a simulation result of a piezoelectric vibrating piece that includes a connecting portion 133 with a width WR of 0.55 mm.

FIG. 5 is a graph illustrating distributions of stress value in the X axis direction in the piezoelectric vibrating piece.

FIG. 6 is a graph illustrating relationships between a length LS of the vibrator in the X axis direction and a length LR of the connecting portion in the X axis direction of the piezoelectric vibrating piece.

FIG. 7 is a graph illustrating a relationship between a width WS of the vibrator in the Z′ axis direction and a width WR of the connecting portion in the Z′ axis direction of the piezoelectric vibrating piece.

FIG. 8 is a graph illustrating a relationship between the length LS of the vibrator in the X axis direction and a length LA of a framing portion in the X axis direction of the piezoelectric vibrating piece.

FIG. 9 is a graph illustrating a relationship between the width WS of the vibrator in the Z′ axis direction and a width WA of the framing portion in the Z′ axis direction of the piezoelectric vibrating piece.

FIG. 10A is a plan view of a piezoelectric vibrating piece 230.

FIG. 10B is a cross-sectional view taken along the line C-C of FIG. 10A.

FIG. 11 is an exploded perspective view of a piezoelectric device 500.

FIG. 12A is a cross-sectional view taken along the line D-D of FIG. 11.

FIG. 12B is a plan view of a piezoelectric vibrating piece 530.

FIG. 13A is a plan view of the piezoelectric vibrating piece 530 without electrodes.

FIG. 13B is a cross-sectional view taken along the line E-E of FIG. 12B.

FIG. 14A is a simulation result of the piezoelectric vibrating piece that includes a connecting portion 533 with a width WR of 0.32 mm.

FIG. 14B is a simulation result of the piezoelectric vibrating piece that includes the connecting portion 533 with a width WR of 0.35 mm.

FIG. 14C is a simulation result of the piezoelectric vibrating piece that includes the connecting portion 533 with a width WR of 0.45 mm.

FIG. 15A is a simulation result of the piezoelectric vibrating piece that includes the connecting portion 533 with a width WR of 0.55 mm.

FIG. 15B is a simulation result of the piezoelectric vibrating piece where the connecting portion is connected at the center of a first side of a vibrator.

FIG. 16 is a graph illustrating a distribution of stress value in the Z′ axis direction applied to a piezoelectric vibrating piece where the connecting portion 533 is connected at an end portion of a first side 538a.

FIG. 17A is a plan view of a piezoelectric vibrating piece 630.

FIG. 17B is a cross-sectional view taken along the line F-F of FIG. 17A.

FIG. 18A is a plan view of a piezoelectric vibrating piece 730.

FIG. 18B is a cross-sectional view taken along the line G-G of FIG. 18A.

### DETAILED DESCRIPTION

Each embodiment of the present invention is described in detail below by referring to the accompanying drawings. It will be understood that the scope of the disclosure is not limited to the described embodiments, unless otherwise stated.

### Configuration of a Piezoelectric Device 100 According to a First Embodiment

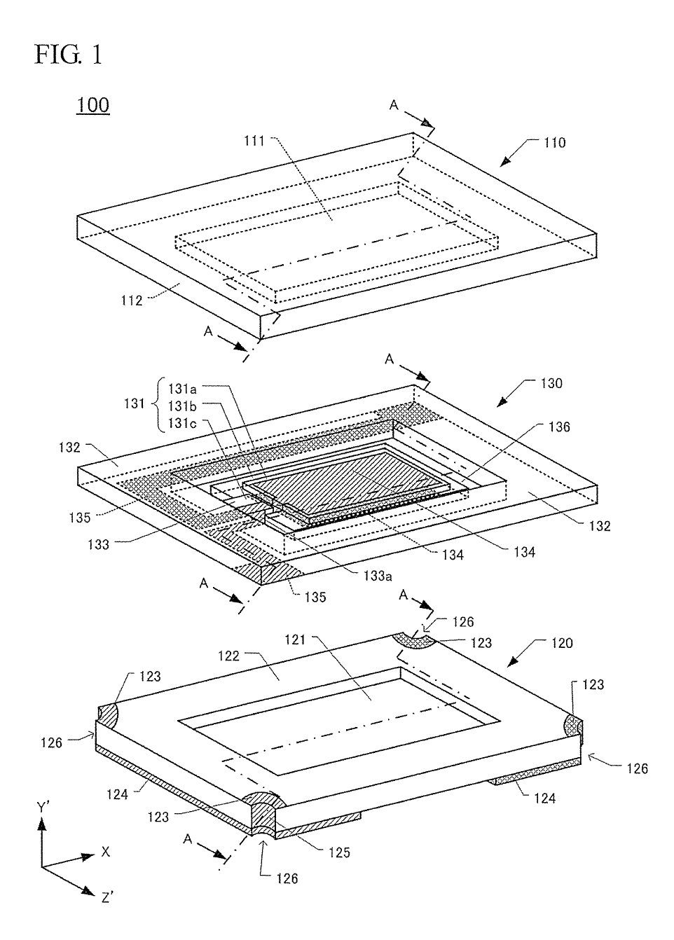

FIG. 1 is an exploded perspective view of the piezoelectric device 100. The piezoelectric device 100 includes a lid plate 110, a base plate 120, and a piezoelectric vibrating piece 130. The piezoelectric vibrating piece 130 employs, for example, an AT-cut quartz-crystal vibrating piece. The AT-cut quartz-crystal vibrating piece has a principal surface (in the Y-Z plane) that is tilted by 35° 15′ about the Y-axis of the crystal coordinate system (XYZ) in the direction from the Z-axis to the Y-axis around the X-axis. In the following description, the new axises tilted with reference to the axis directions of the AT-cut quartz-crystal vibrating piece are denoted as the Y′ axis and the Z′ axis. Therefore, in the piezoelectric device 100, the longitudinal direction of the piezoelectric device 100 is referred as the X axis direction, the height direction of the piezoelectric device 100 is referred as the Y′ axis direction, and the direction perpendicular to the X axis and the Y′ axis directions is referred to as the Z′ axis direction.

The piezoelectric vibrating piece 130 includes a vibrator 131, which vibrates at a predetermined vibration frequency, a framing portion 132, which surrounds the vibrator 131, and a connecting portion 133, which connects the framing portion 132 and the vibrator 131 together. The vibrator 131 includes excitation electrodes 134, which are formed on surfaces at the +Y′ axis side and the −Y′ axis side of the vibrator 131. From the excitation electrodes 134, respective extraction electrodes 135 are extracted via the connecting portion 133 to the framing portion 132.

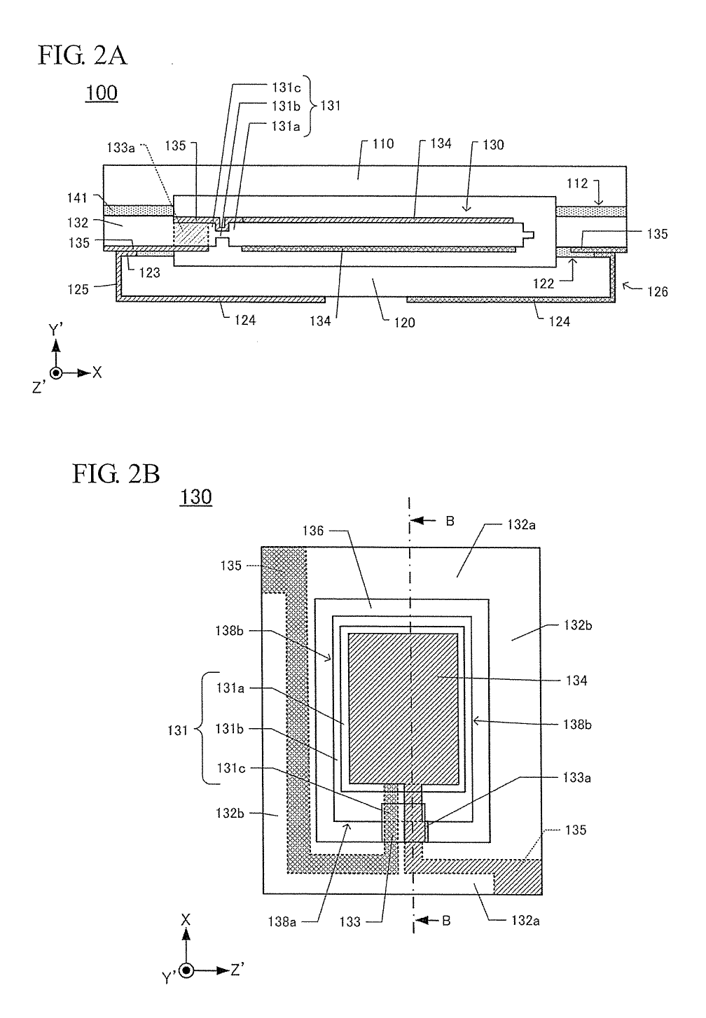

The base plate 120 is disposed at the −Y′ axis side of the piezoelectric vibrating piece 130. The base plate 120 is formed in a rectangular shape that has long sides in the X axis direction and short sides in the Z′ axis direction. The base plate 120 includes a pair of external electrodes 124 on the surface at the −Y′ axis side. The external electrodes 124 are secured and electrically connected to a printed circuit board or the like via solder. This mounts the piezoelectric device 100 on the printed circuit board or the like. On side faces at four corners of the base plate 120, castellations 126 are formed, while castellation electrodes 125 are formed on the castellations 126. The base plate 120 includes a recess 121 on the surface at the +Y′ axis side, while a bonding surface 122 is formed in a peripheral area of the recess 121. The bonding surface 122 includes coupling electrodes 123 in peripheral areas of the castellations 126 at the four corners. The coupling electrodes 123 are electrically connected to the external electrodes 124 via the castellation electrodes 125 on the castellation 126. The base plate 120 is bonded to the surface of the framing portion 132 at the −Y′ axis side in the piezoelectric vibrating piece 130 via a sealing material 141 (see FIGS. 2A and 2B) on the bonding surface 122. The coupling electrodes 123 are electrically connected to the extraction electrodes 135 of the piezoelectric vibrating piece 130.

The lid plate 110 is disposed at the +Y′ axis side of the piezoelectric vibrating piece 130. The lid plate 110 includes a recess 111 on its surface at the −Y′ axis side, while a bonding surface 112 is formed in a peripheral area of the recess 111. The lid plate 110 is bonded to the surface of the framing portion 132 at the +Y′ axis side in the piezoelectric vibrating piece 130 via the sealing material 141 (see FIGS. 2A and 2B) on the bonding surface 112.

FIG. 2A is a cross-sectional view taken along the line A-A of FIG. 1. The piezoelectric device 100 is bonded to the bonding surface 112 of the lid plate 110 at the +Y′ axis side of the framing portion 132 in the piezoelectric vibrating piece 130 via the sealing material 141, while the piezoelectric device 100 is bonded to the bonding surface 122 of the base plate 120 at the surface at the −Y′ axis side of the framing portion 132 via the sealing material 141. When the piezoelectric vibrating piece 130 and the base plate 120 are bonded together, the extraction electrodes 135 and the coupling electrodes 123 are electrically connected to one another. The extraction electrodes 135 are formed on the −Y′ axis side of the framing portion 132. The coupling electrodes 123 are formed on the bonding surface 122 of the base plate 120. Thus, respective excitation electrodes 134, which are formed on the +Y′ axis side and the −Y′ axis side of a mesa region 131a, are electrically connected to the external electrodes 124 via the extraction electrode 135, the coupling electrode 123, and the castellation electrode 125.

FIG. 2B is a plan view of the piezoelectric vibrating piece 130. The piezoelectric vibrating piece 130 includes the vibrator 131 in a rectangular shape, the framing portion 132, which surrounds the vibrator 131, the one connecting portion 133, which connects the vibrator 131 and the framing portion 132 together. The vibrator 131 includes a first side 138a, which is a side of the vibrator 131 at the −X axis side, and second sides 138b, which are sides of the vibrator 131 at the +Z′ axis side and the −Z′ axis side. The framing portion 132 includes first frames 132a, which extend in the Z′ axis direction and second frames 132b, which extend in the X axis direction. The first frames 132a are disposed at the +X axis side and the −X axis side of the vibrator 131, while the second frames 132b are disposed at the +Z′ axis side and the −Z′ axis side of the vibrator 131. The connecting portion 133 is connected to the center of the first side 138a in the vibrator 131, and then extends from this center to the −X axis direction, thus being connected to the center of the first frame 132a at the −X axis side. A region, which is other than the connecting portion 133, between the vibrator 131 and the framing portion 132 forms a through hole 136 that passes through the piezoelectric vibrating piece 130 in the Y′ axis direction. The vibrator 131 includes the mesa region 131a with the excitation electrodes 134, a peripheral region 131b around the mesa region 131a, and a connecting region 131c, which is directly connected to the connecting portion 133. The peripheral region 131b is formed between the mesa region 131a and the connecting region 131c, while the mesa region 131a and the connecting region 131c do not contact one another. From the excitation electrode 134 on the surface at the +Y′ axis side of the mesa region 131a, an extraction electrode 135 is extracted via the peripheral region 131b, the connecting region 131c, the surface at the +Y′ axis side of the connecting portion 133, the side face 133a at the +Z′ axis side of the connecting portion 133, and the surface at the −Y′ axis side of the connecting portion 133. The extraction electrode 135 is extracted to a corner portion at the −X axis side and the +Z′ axis side on the surface at the −Y′ axis side of the framing portion 132. From the excitation electrode 134 (see FIG. 2A) on the surface at the −Y′ axis side of the mesa region 131a, an extraction electrode 135 is extracted to the framing portion 132 via the peripheral region 131b, the connecting region 131c, and the surface at the −Y′ axis side of the connecting portion 133. The extraction electrode 135 further extends to the −Z′ axis direction and the +X axis direction on the surface at the −Y′ axis side of the framing portion 132, and is extracted to a corner portion at the +X axis side and the −Z′ axis side on the surface at the −Y′ axis side of the framing portion 132. The extraction electrode 135 that is extracted from the excitation electrode 134 on the surface at the −Y′ axis side is extracted to the +X axis side of the framing portion 132. Thus, this extraction electrode 135 has a longer formation distance than that of the extraction electrode 135 that is extracted from the excitation electrode 134 on the surface at the +Y′ axis side.

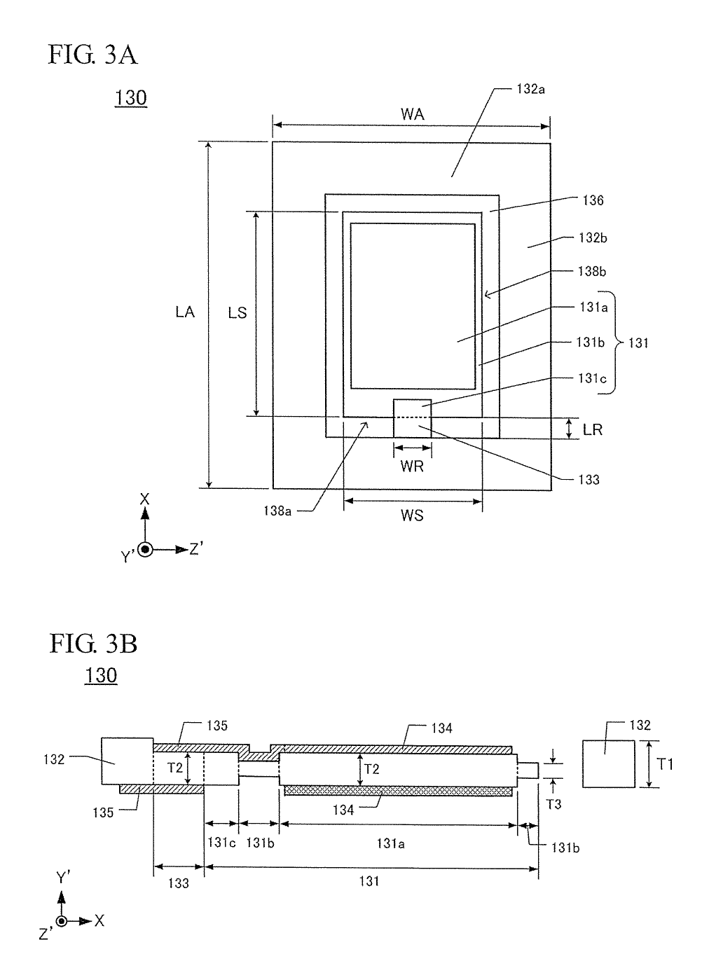

FIG. 3A is a plan view of the piezoelectric vibrating piece 130 without electrodes. The vibrator 131 has the first side 138a with a length WS and the second side 138b with a length LS. Assume that in the piezoelectric vibrating piece 130, the whole first frame 132a of the framing portion 132 has a length WA in the Z′ axis direction, the whole second frame 132b of the framing portion 132 has a length LA in the X axis direction, the connecting portion 133 has a width WR in the Z′ axis direction, and the connecting portion 133 has a length LR in the X axis direction.

FIG. 3B is a cross-sectional view taken along the line B-B of FIG. 2B. Assume that in the piezoelectric vibrating piece 130, the framing portion 132 has a thickness T1 in the Y′ axis direction, the connecting portion 133, the connecting region 131c of the vibrator 131, and the mesa region 131a each have a thickness T2 in the Y′ axis direction, and the peripheral region 131b of the vibrator 131 has a thickness T3 in the Y′ axis direction. That is, the connecting portion 133 and the connecting region 131c are directly connected to each other with the thickness T2. In the piezoelectric vibrating piece 130, the thickness T1 is thicker than the thickness T2 and the thickness T3, while the thickness T2 is thicker than the thickness T3.

### Measurement of Stress Characteristics of Piezoelectric Vibrating Pieces

Simulations to predict stresses on piezoelectric vibrating pieces, and measurement of stress characteristics of produced piezoelectric vibrating pieces were performed. This carries out experiments to determine appropriate dimensions of the piezoelectric vibrating pieces that reduce stresses on vibrators of the piezoelectric vibrating pieces. Simulation results of the piezoelectric vibrating pieces and the measurement results of characteristics of the piezoelectric vibrating pieces will be described below.

### Simulation Results

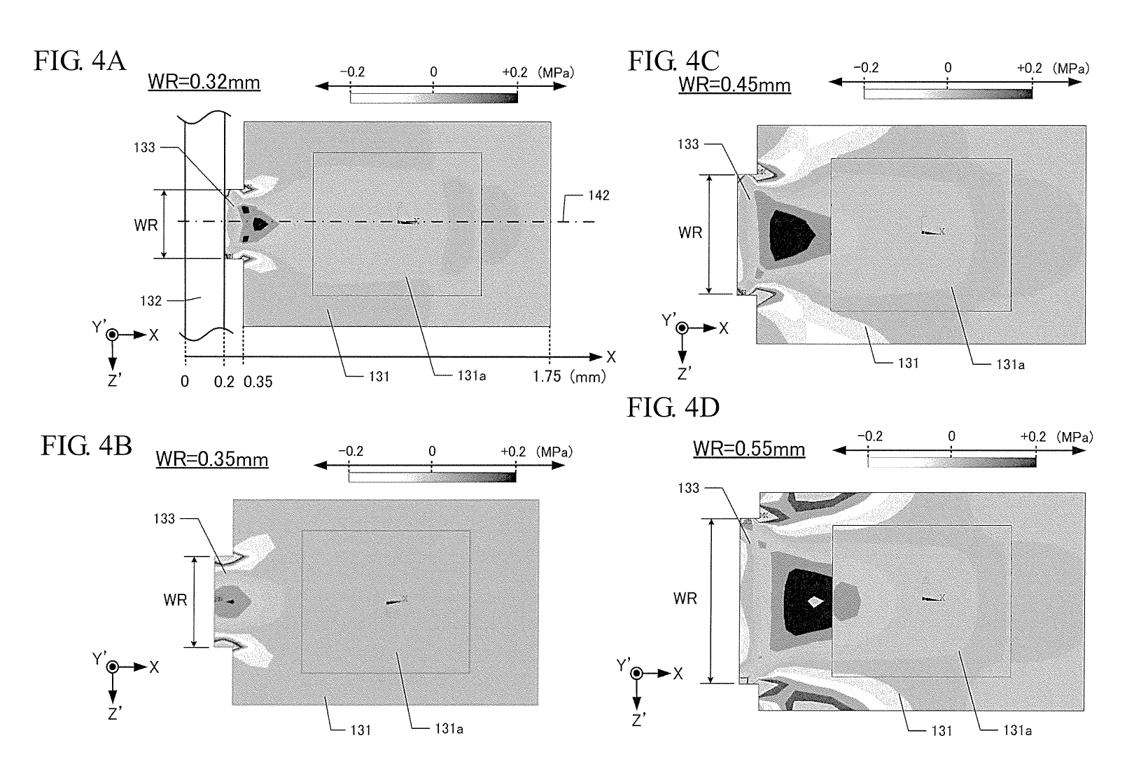

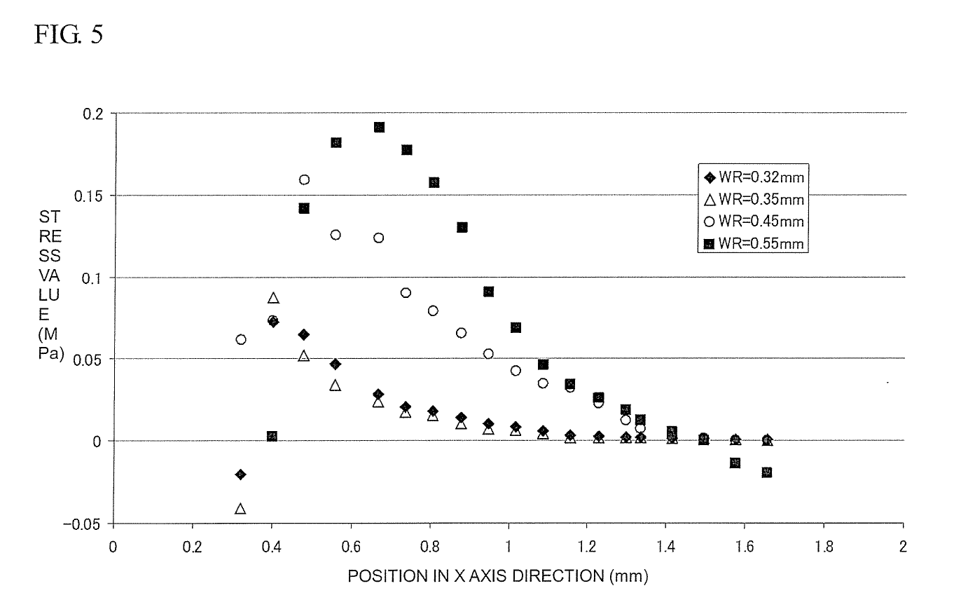

In the case where the piezoelectric devices are mounted on printed circuit boards, simulations are performed to calculate stresses on the piezoelectric vibrating pieces when the printed circuit boards are bent. Simulation results will be described by referring to FIGS. 4A to 4D and FIG. 5. In the following simulations, dimensions of the piezoelectric vibrating pieces are each assumed to have the length LA of 2.0 mm, the length WA of 1.6 mm, the length LS of 1.4 mm, the length WS of 1.375 mm, and the length LR of 0.15 mm. These simulations examined variation of stresses on the piezoelectric vibrating pieces in the case where the width WR of the connecting portion 133 is changed.

FIG. 4A is a simulation result of a piezoelectric vibrating piece that includes a connecting portion 133 with a width WR of 0.32 mm. FIG. 4A is a plan view of the vibrator 131 and the connecting portion 133, illustrating a simulation result. In the simulation result, a gray region shows a region where approximately no stress in the X axis direction is applied to the piezoelectric vibrating piece. Tensile stress in the X axis direction on the piezoelectric vibrating piece becomes larger as the color becomes darker from the gray to black. Compressive stress in the X axis direction on the piezoelectric vibrating piece becomes larger as the color becomes lighter from the gray to white. In the piezoelectric vibrating piece illustrated in FIG. 4A, a stress is applied to a region adjacent to the connected connecting portion 133 of the vibrator 131. Since the mesa region 131a is approximately the gray region, it shows that almost no stress is applied to the mesa region 131a.

FIG. 4B is a simulation result of a piezoelectric vibrating piece that includes a connecting portion 133 with a width WR of 0.35 mm. In the piezoelectric vibrating piece illustrated in FIG. 4B, colors of regions in the +Z′ axis side and the −Z′ axis side of the connecting portion 133 are brighter than the gray. A color of a region covering the center of the connecting portion 133 and its vicinity is also darker than the gray. This shows stresses are applied to these regions. Since the mesa region 131a is approximately the gray region, it shows that almost no stress is applied to the mesa region 131a.

FIG. 4C is a simulation result of a piezoelectric vibrating piece that includes a connecting portion 133 with a width WR of 0.45 mm. In the piezoelectric vibrating piece illustrated in FIG. 4C, a color of a region between the connecting portion 133 and the mesa region 131a is darker than the gray. This shows a large stress is applied to this region. Since a color of the mesa region 131a is brighter than the gray, some stresses are applied to the mesa region 131a.

FIG. 4D is a simulation result of a piezoelectric vibrating piece that includes a connecting portion 133 with a width WR of 0.55 mm. In the piezoelectric vibrating piece illustrated in FIG. 4D, large stresses are applied to: a region between the connecting portion 133 and the mesa region 131a; and the −X axis sides of the respective sides parallel to the X axis in the vibrator 131. Since the mesa region 131a has a color that is darker than the gray and another color that is lighter than the gray, it shows that some stresses are applied to the mesa region 131a.

FIG. 5 is a graph illustrating distributions of stress value in the X axis direction of the piezoelectric vibrating piece. The horizontal axis of the graph illustrates positions on a straight line 142 (see FIG. 4A), which passes through the center of the connecting portion 133 in the piezoelectric vibrating piece and is parallel to the X axis. Further, the graph will be described by referring to FIG. 4A. FIG. 5 illustrates positions in the +X axis direction from an end, which is assumed to be a position of 0 mm, at the −X axis side of the framing portion 132 at the −X axis side. The vertical axis in FIG. 5 illustrates stress in the X axis direction on the piezoelectric vibrating piece. Positive values indicate tensile stress, while negative values indicate compressive stress. In FIG. 5, black diamonds indicate the piezoelectric vibrating piece with the width WR of 0.32 mm, white triangles indicate the piezoelectric vibrating piece with the width WR of 0.35 mm, white circle indicate the piezoelectric vibrating piece with the width WR of 0.45 mm, and black squares indicate the piezoelectric vibrating piece with the width WR of 0.55 mm.

The piezoelectric vibrating piece with the width WR of 0.55 mm takes the maximum stress value of about 0.19 MPa at the position of 0.67 mm in the X axis direction. The piezoelectric vibrating piece with the width WR of 0.45 mm takes the maximum stress value of about 0.16 MPa at the position of 0.48 mm in the X axis direction. The piezoelectric vibrating piece with the width WR of 0.35 mm takes the maximum stress value of about 0.09 MPa at the position of 0.40 mm in the X axis direction. The piezoelectric vibrating piece with the width WR of 0.32 mm takes the maximum stress value of about 0.07 MPa at the position of 0.48 mm in the X axis direction.

It is preferred that the stress on the piezoelectric vibrating piece be equal to or less than 0.1 MPa, considering change in vibration frequency of the piezoelectric vibrating piece. According to FIG. 5, the piezoelectric vibrating piece with the width WR of 0.55 mm and the piezoelectric vibrating piece with the width WR of 0.45 mm each have the maximum value of stress, which is applied to the piezoelectric vibrating piece, exceeding 0.1 MPa. In contrast, the piezoelectric vibrating piece with the width WR of 0.35 mm and the piezoelectric vibrating piece with the width WR of 0.32 mm each have the preferred maximum value of stress, which is applied to the piezoelectric vibrating piece, below 0.1 MPa. That is, it is preferred that the width WR of the piezoelectric vibrating piece be equal to or less than 0.40 mm, which is a medium value of 0.45 mm, which results in the maximum stress value exceeding 0.1 MPa, and 0.35 mm, which results in the maximum stress value equal to or less than 0.1 MPa.

### Measurement Result of Characteristics of the Piezoelectric Vibrating Pieces

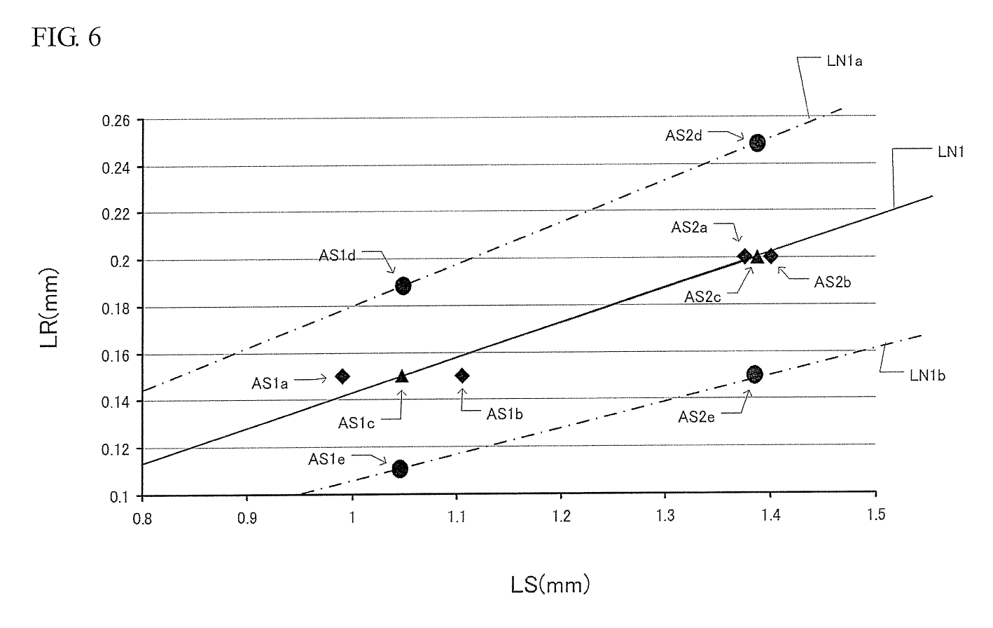

The piezoelectric devices are produced and each mounted on a printed circuit board. Then, characteristics such as vibration frequency and crystal impedance (CI) value of the piezoelectric vibrating piece are measured. Based on measurement results of the characteristics, preferred dimensions of piezoelectric vibrating piece are calculated. In the following description, degradation of characteristic of the piezoelectric vibrating piece means variation in vibration frequency or increase in CI value of the piezoelectric vibrating piece. The produced piezoelectric devices employ a piezoelectric vibrating piece with the width WR of equal to or less than 0.40 mm, which is a preferred piezoelectric vibrating piece based on the simulation results. Hereinafter, measurement results of the characteristics of the piezoelectric vibrating pieces will be described by referring to FIG. 6 to FIG. 9.

FIG. 6 is a graph illustrating relationships between the length LS of the vibrator 131 in the X axis direction and the length LR of the connecting portion 133 in the X axis direction of the piezoelectric vibrating piece. In FIG. 6, the characteristics of the piezoelectric vibrating piece are measured regarding a piezoelectric vibrating piece AS1 and a piezoelectric vibrating piece AS2 in the case where the length LS of the vibrator 131 is changed. The piezoelectric vibrating piece AS1 has dimensions of the length LA of 2.0 mm, the length WA of 1.6 mm, the length WS of 1.375 mm, the length LR of 0.15 mm, and the width WR of 0.32 mm. The piezoelectric vibrating piece AS2 has dimensions of the length LA of 2.0 mm, the length WA of 1.6 mm, the length WS of 0.872 mm, the length LR of 0.2 mm, and the width WR of 0.37 mm. In the graph of FIG. 6, the length LS is on the horizontal axis while the length LR is on the vertical axis. In FIG. 6, black diamonds and black circles indicate measured values. Black triangles indicate average values that are calculated based on the measured values of the black diamonds.

In the piezoelectric vibrating piece AS1, the characteristics of the piezoelectric vibrating piece are examined in cases of a vibrator 131 with a length LS of 0.99 mm (a point AS1a in FIG. 6) and a vibrator 131 with a length LS of 1.105 mm (a point AS1b in FIG. 6). This provides both the piezoelectric vibrating pieces with satisfactory characteristics. Accordingly, in the piezoelectric vibrating piece AS1, a vibrator 131 with a length LS of 1.0475 mm (a point AS1C in FIG. 6), which is a medium value of the two points, has preferred characteristics. In the piezoelectric vibrating piece AS2, characteristics of the piezoelectric vibrating piece are examined in cases of a vibrator 131 with a length LS of 1.375 mm (a point AS2a in FIG. 6) and a vibrator 131 with a length LS of 1.4 mm (a point AS2b in FIG. 6). This provides both the piezoelectric vibrating pieces with satisfactory characteristics. Accordingly, in the piezoelectric vibrating piece AS2, a vibrator 131 with a length LS of 1.3875 mm (a point AS2c in FIG. 6), which is a medium value of two points, has preferred characteristics. That is, it is preferred that the piezoelectric vibrating piece satisfy a relationship between the length LR and the length LS that is expressed by the straight line LN1 passing through the point AS1c and the point AS2c in FIG. 6. The straight line LN1 is expressed by the following equation 1.

LR=0.1471×LS−0.004 Equation (1)

In contrast, in the case where the piezoelectric vibrating piece AS1 has the length LS of 1.0475 mm (the point AS1c in FIG. 6), and a value of the length LR was increased from 1.5 mm, the piezoelectric vibrating piece was damaged in a drop test of the piezoelectric device when the value of the length LR became 0.19 mm (a point AS1d of FIG. 6). Similarly, in the case where the piezoelectric vibrating piece AS2 has the length LS of 1.3875 mm (the point AS2c in FIG. 6), and a value of the length LR was increased from 0.2 mm, the piezoelectric vibrating piece was damaged in a drop test of the piezoelectric device when the value of the length LR became 0.25 mm (a point AS2d in FIG. 6). That is, it is preferred that the length LR of the piezoelectric vibrating piece be shorter than a length LR that is derived from a straight line LN1a passing through the point AS1d and the point AS2d. A length LR that is derived from the straight line LN1a is about 25 percent more than a length LR that is derived from the straight line LN1.

A board bending test was performed on the piezoelectric vibrating pieces. The board bending test is a test that examines variation in vibration frequency of the piezoelectric vibrating piece when bending a printed circuit board on which the piezoelectric device is mounted. In the case where the piezoelectric vibrating piece AS1 has the length LS of 1.0475 mm (the point AS1c in FIG. 6), and the value of the length LR was decreased from 1.5 mm, vibration frequency of the piezoelectric vibrating piece considerably changed when the value of the length LR became 1.125 mm (a point AS1e in FIG. 6). Similarly, in the case where the piezoelectric vibrating piece AS2 has the length LS of 1.3875 mm (the point AS2c in FIG. 6), and the value of the length LR was decreased from 0.2 mm, vibration frequency of the piezoelectric vibrating piece considerably changed when the value of the length LR became 0.15 mm (a point AS2e in FIG. 6). It is assumed that these changes in vibration frequency of the piezoelectric vibrating pieces are caused by the shortened length LR of the connecting portion 133. The reason is that the shortened length LR of the connecting portion 133 increases stress, which transfers from the printed circuit board to the mesa region 131a via the framing portion 132. That is, it is preferred that the piezoelectric vibrating piece have the length LR that is larger than that derived from a straight line LN1b passing through the point AS1e and the point AS2e. This length LR that is derived from the straight line LN1b is about 25 percent less than a length LR that is derived from the straight line LN1.

As described above, it is preferred that the relationship between the length LS and the length LR of the piezoelectric vibrating piece be as follows. The length LR of the piezoelectric vibrating piece is less than 125% and more than 75% of the length LR that is derived from the straight line LN1. That is, it is preferred that the relationship in the piezoelectric vibrating piece between the length LS and the length LR satisfy equation 2 below.

(0.1471×LS−0.004)×0.75<LR<(0.1471×LS−0.004)×1.25 Equation (2)

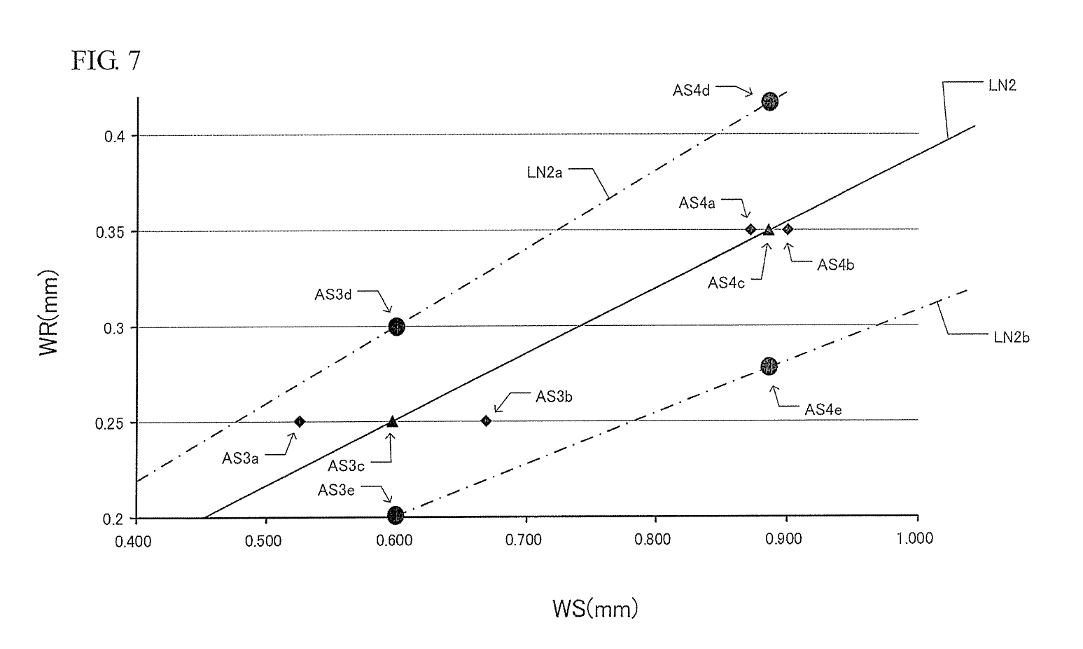

FIG. 7 is a graph illustrating a relationship between the length WS of the vibrator 131 in the Z′ axis direction and the width WR of the connecting portion 133 in the Z′ axis direction of the piezoelectric vibrating piece. In FIG. 7, the characteristics of the piezoelectric vibrating piece are measured regarding a piezoelectric vibrating piece AS3 and a piezoelectric vibrating piece AS4 in the case where the length WS of the vibrator 131 is changed. The piezoelectric vibrating piece AS3 has dimensions of the length LA of 2.0 mm, the length WA of 1.6 mm, the length LS of 0.9 mm, the length LR of 0.2 mm, and the width WR of 0.35 mm. The piezoelectric vibrating piece AS4 has dimensions of the length LA of 1.6 mm, the length WA of 1.2 mm, the length LS of 0.668 mm, the length LR of 0.14 mm, and the width WR of 0.25 mm. In the graph of FIG. 7, the length WS is on the horizontal axis while the width WR is on the vertical axis. In FIG. 7, black diamonds and the black circles indicate measured values while black triangles indicate average values that are calculated based on the measured values of the black diamonds.

In the piezoelectric vibrating piece AS3, the characteristics of the piezoelectric vibrating piece were examined in cases of a vibrator 131 with a length WS of 0.525 mm (a point AS3a in FIG. 7) and a vibrator 131 with a length WS of 0.668 mm (a point AS3b in FIG. 7). This provides both the piezoelectric vibrating pieces with satisfactory characteristics. Accordingly, in the piezoelectric vibrating piece AS3, a vibrator 131 with a length WS of 0.5965 mm (a point AS3c in FIG. 7), which is a medium value of the two points, is assumed to have preferred characteristics. In the piezoelectric vibrating piece AS4, the characteristics of the piezoelectric vibrating pieces were examined in cases of a vibrator 131 with a length WS of 0.872 mm (a point AS4a in FIG. 7) and a vibrator 131 with a length WS of 0.9 mm (a point AS4b in FIG. 7). This provides both the piezoelectric vibrating pieces with satisfactory characteristics. Accordingly, in the piezoelectric vibrating piece AS4, a vibrator 131 with a length WS of 0.886 mm (a point AS4c in FIG. 7), which is a medium value of the two points, is assumed to have preferred characteristics. That is, this piezoelectric vibrating piece is assumed to satisfy a relationship between the width WR and the length WS, which is expressed by a straight line LN2 passing through the point AS3c and the point AS4c in FIG. 7. The straight line LN2 is expressed by equation 3 below.

WR=0.3545×WS+0.044 Equation (3)

In contrast, in the case where the piezoelectric vibrating piece AS3 has the length WS of 0.5965 mm (a point AS3c in FIG. 7), and a value of the width WR was increased from 0.25 mm, vibration frequency of the piezoelectric vibrating piece considerably changed in the board bending test when the value of the width WR became 0.3 mm (a point AS3d in FIG. 7). Similarly, in the case where the piezoelectric vibrating piece AS4 has the length WS of 0.886 mm (the point AS4c of FIG. 7), and a value of the width WR was increased from 0.35 mm, vibration frequency of the piezoelectric vibrating piece considerably changed in the board bending test when the value of the width WR became 0.42 mm (a point AS4d in FIG. 7). It is assumed that these changes in vibration frequency of the piezoelectric vibrating pieces are caused by the increased width WR of the connecting portion 133. The reason is that the increased width WR increases stress, which transfers from the printed circuit board to the mesa region 131a via the framing portion 132. That is, it is preferred that the piezoelectric vibrating piece have the width WR that is narrower than the width WR derived from a straight line LN2a passing through the point AS3d and the point AS4d. The width WR that is derived from the straight line LN2a is about 20 percent more than the width WR derived from the straight line LN2.

In the case where the piezoelectric vibrating piece AS3 has the length WS of 0.5965 mm (a point AS3c in FIG. 7), and a value of the width WR was decreased from 0.25 mm, the piezoelectric vibrating piece was damaged in a drop test of the piezoelectric device when the value of the width WR became 0.2 mm (a point AS3e in FIG. 7). Similarly, in the case where the piezoelectric vibrating piece AS4 has the length WS of 0.886 mm (the point AS4c of FIG. 7), and a value of the width WR was decreased from 0.35 mm, the piezoelectric vibrating piece was damaged in a drop test of the piezoelectric device when the value of the width WR became 0.28 mm (a point AS4e in FIG. 7). That is, it is preferred that the piezoelectric vibrating piece have the width WR that is larger than that derived from a straight line LN2b passing through the point AS3e and the point AS4e. This width WR that is derived from the straight line LN2b is about 20 percent less than the width WR derived from the straight line LN2.

As described above, it is preferred that the relationship in the piezoelectric vibrating piece between the length WS and the width WR be as follows. The width WR of the piezoelectric vibrating piece is less than 120% and more than 80% of the width WR that is derived from the straight line LN2. That is, it is preferred that the relationship in the piezoelectric vibrating piece between the length WS and the width WR satisfy equation 4 below.

(0.3545×WS+0.044)×0.8<WR<(0.3545×WS+0.044)×1.2 Equation (4)

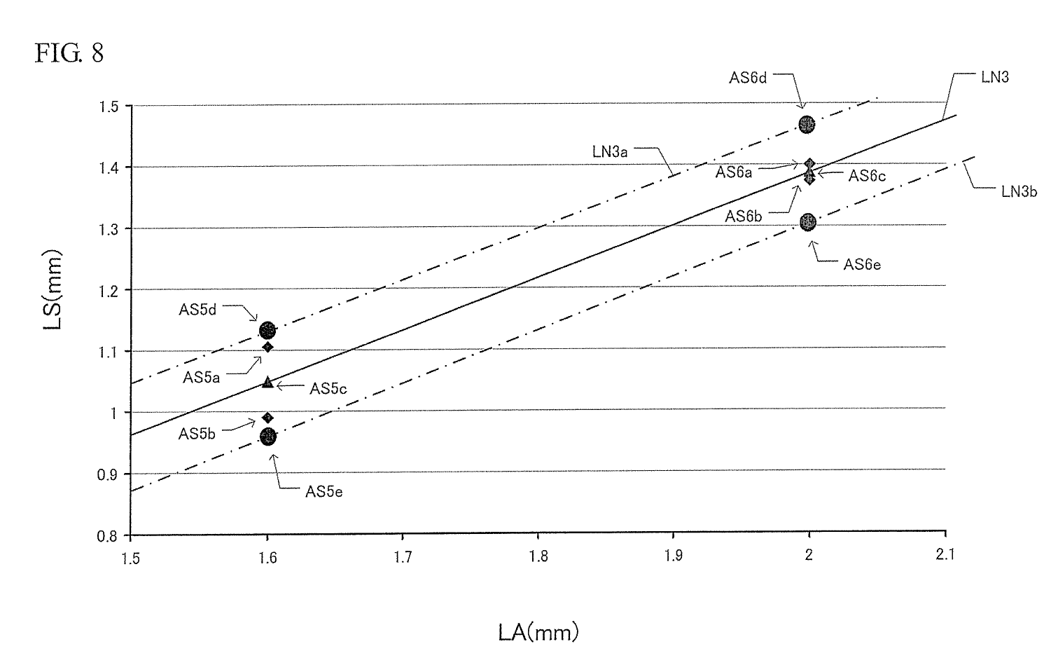

FIG. 8 is a graph illustrating a relationship between the length LS of the vibrator 131 in the X axis direction and the length LA of the framing portion 132 in the X axis direction of the piezoelectric vibrating piece. In FIG. 8, the characteristics of the piezoelectric vibrating piece are measured regarding a piezoelectric vibrating piece AS5 and a piezoelectric vibrating piece AS6 in the case where the length LS of the vibrator 131 is changed. The piezoelectric vibrating piece AS5 has dimensions of the length LA of 2.0 mm, the length WA of 1.6 mm, the length WS of 1.375 mm, the length LR of 0.15 mm, and the width WR of 0.32 mm. The piezoelectric vibrating piece AS6 has dimensions of the length LA of 1.6 mm, the length WA of 1.2 mm, the length WS of 0.99 mm, the length LR of 0.12 mm, and the width WR of 0.22 mm. In the graph of FIG. 8, the length LA is on the horizontal axis while the length LS is on the vertical axis. In FIG. 8, black diamonds and black circles indicate measured values, while black triangles indicate average values that are calculated based on the measured values of the black diamonds.

In the piezoelectric vibrating piece AS5, the characteristics of the piezoelectric vibrating piece were examined in cases of a vibrator 131 with a length LS of 1.105 mm (a point AS5a in FIG. 8) and a vibrator 131 with a length LS of 0.99 mm (a point AS5b in FIG. 8). This provides both the piezoelectric vibrating pieces with satisfactory characteristics. Accordingly, in the piezoelectric vibrating piece AS5, a vibrator 131 with a length LS of 1.0475 mm (a point AS5c in FIG. 8), which is a medium value of the two points, is assumed to have preferred characteristics. In the piezoelectric vibrating piece AS6, the characteristics of the piezoelectric vibrating piece were examined in cases of a vibrator 131 with a length LS of 1.4 mm (a point AS6a in FIG. 8) and a vibrator 131 with a length LS of 1.375 mm (a point AS6b in FIG. 8). This provides both the piezoelectric vibrating pieces with satisfactory characteristics. Accordingly, in the piezoelectric vibrating piece AS6, a vibrator 131 with a length LS of 1.3875 mm (a point AS6c in FIG. 8), which is a medium value of two points, is assumed to have preferred characteristics. That is, it is preferred that the piezoelectric vibrating piece satisfy a relationship between the length LA and the length LS, which is expressed by a straight line LN3 passing through the point AS5c and the point AS6c in FIG. 8. The straight line LN3 is expressed by equation 5 below.

LS=0.85×LA−0.3125 Equation (5)

In contrast, assume that a value of the length LS was increased from 1.0475 mm (the point AS5c in FIG. 8) regarding the piezoelectric vibrating piece AS5. When a value of the length LS becomes larger than 1.1104 mm (a point AS5d in FIG. 8), the width of the through hole 136 (see FIG. 2B) narrows. This makes it difficult to form the through hole 136 by wet etching. Similarly, assume that a value of the length LS was increased from 1.3875 mm (the point AS6c in FIG. 8) regarding the piezoelectric vibrating piece AS6. When a value of the length LS becomes larger than 1.4708 mm (a point AS6d in FIG. 8), the width of the through hole 136 (see FIG. 2B) narrows. This makes it difficult to form the through hole 136 by wet etching. That is, it is preferred that the length LS of the piezoelectric vibrating piece be shorter than the length LS that is derived from a straight line LN3a passing through the point AS5d and the point AS6d. The length LS that is derived from the straight line LN3a is about 6 percent more than the length LS derived from the straight line LN3.

Assume that a value of the length LS was decreased from 1.0475 mm (the point AS5c in FIG. 8) regarding the piezoelectric vibrating piece AS5. When the value of the length LS becomes smaller than 0.9846 mm (a point AS5e in FIG. 8), a CI value exceeds its preferred range as a product. Similarly, assume that a value of the length LS was decreased from 1.3875 mm (the point AS6c in FIG. 8) regarding the piezoelectric vibrating piece AS6. When the value of the length LS became smaller than 1.3042 mm (a point AS6e in FIG. 8), a CI value exceeds its preferred range as a product. That is, it is preferred that the length LS of the piezoelectric vibrating piece be larger than the length LS derived from a straight line LN3b passing through the point AS5e and the point AS6e. The length LS that is derived from the straight line LN3b is about 6 percent less than the length LS derived from the straight line LN3.

As described above, it is preferred that the relationship in the piezoelectric vibrating piece between the length LS and the length LA be as follows. The length LS is less than 106% and more than 94% of the length LS derived from the straight line LN3. That is, it is preferred that the relationship in the piezoelectric vibrating piece between the length LS and the length LA satisfy equation 6 below.

(0.85×LA−0.3125)×0.94<LS<(0.85×LA−0.3125)×1.06 Equation (6)

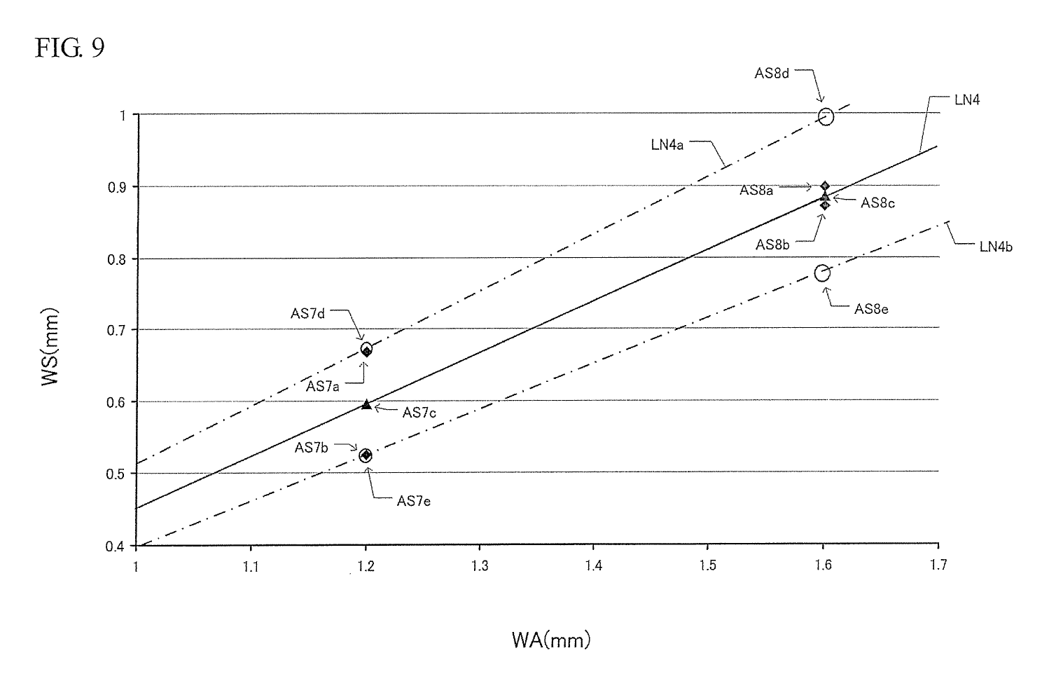

FIG. 9 is a graph illustrating a relationship between the length WS of the vibrator 131 in the Z′ axis direction and the length WA of the framing portion 132 in the Z′ axis direction of the piezoelectric vibrating piece. In FIG. 9, the characteristics of the piezoelectric vibrating piece were measured regarding a piezoelectric vibrating piece AS7 and a piezoelectric vibrating piece AS8 in the case where the length WS of the vibrator 131 is changed. The piezoelectric vibrating piece AS7 has dimensions of the length LA of 2.0 mm, the length WA of 1.6 mm, the length LS of 0.9 mm, the length LR of 0.2 mm, and the width WR of 0.37 mm. The piezoelectric vibrating piece AS8 has dimensions of the length LA of 1.6 mm, the length WA of 1.2 mm, the length LS of 0.668 mm, the length LR of 0.14 mm, and the width WR of 0.24 mm. In the graph of FIG. 9, the length WA is on the horizontal axis while the length WS is on the vertical axis. In FIG. 9, black diamonds and white circles indicate measured values, while black triangles indicate average values that are calculated based on the measured values of the black diamonds.

In the piezoelectric vibrating piece AS7, the characteristics of the piezoelectric vibrating piece were examined in cases of a vibrator 131 with a length WS of 0.668 mm (a point AS7a in FIG. 9) and a vibrator 131 with a length WS of 0.525 mm (a point AS7b in FIG. 9). This provides both the piezoelectric vibrating pieces with satisfactory characteristics. Accordingly, in the piezoelectric vibrating piece AS7, a vibrator 131 with a length WS of 0.597 mm (a point AS7c in FIG. 9), which is a medium value of the two points, is assumed to have preferred characteristics. In the piezoelectric vibrating piece AS8, the characteristics of the piezoelectric vibrating piece were examined in cases of a vibrator 131 with a length WS of 0.9 mm (a point AS8a in FIG. 9), and a vibrator 131 with a length WS of 0.872 mm (a point AS8b in FIG. 9). This provides both the piezoelectric vibrating pieces with satisfactory characteristics. Accordingly, in the piezoelectric vibrating piece AS8, a vibrator 131 with a length WS of 0.886 mm (a point AS8c in FIG. 9), which is a medium value of the two points, is assumed to have preferred characteristics. That is, it is preferred that the piezoelectric vibrating piece satisfy a relationship between the length WA and the length WS, which is expressed by a straight line LN4 passing through the point AS7c and the point AS8c in FIG. 9. The straight line LN4 is expressed by equation 7 below.

WS=0.7237×WA−0.272 Equation (7)

In contrast, assume that a value of the length WS was increased from 0.597 mm (the point AS7c in FIG. 9) regarding the piezoelectric vibrating piece AS7. When a value of the length WS becomes larger than 0.6687 mm (a point AS7d in FIG. 9), the width of the through hole 136 (see FIG. 2B) narrows. This makes it difficult to form the through hole 136 by wet etching. Similarly, assume that a value of the length WS was increased from 0.886 mm (the point AS8c in FIG. 9) regarding the piezoelectric vibrating piece AS8. When a value of the length WS becomes larger than 0.9924 mm (a point AS8d in FIG. 9), the width of the through hole 136 (see FIG. 2B) narrows. This makes it difficult to form the through hole 136 by wet etching. That is, it is preferred that the length WS of the piezoelectric vibrating piece be shorter than the length WS that is derived from a straight line LN4a passing through the point AS7d and the point AS8d. The length WS that is derived from the straight line LN4a is about 12 percent more than the length WS derived from the straight line LN4.

Assume that a value of the length WS was decreased from 0.597 mm (the point AS7c in FIG. 9) regarding the piezoelectric vibrating piece AS7. When a value of the length WS becomes smaller than 0.525 mm (a point AS7e in FIG. 9), a CI value exceeds its preferred range as a product. Similarly, assume that a value of the length WS was decreased from 0.886 mm (the point AS8c in FIG. 9) regarding the piezoelectric vibrating piece AS8. When a value of the length WS becomes smaller than 0.7796 mm (a point AS8e in FIG. 9), a CI value exceeds its preferred range as a product. That is, it is preferred that the length WS of the piezoelectric vibrating piece be larger than the length WS that is derived from a straight line LN4b passing through the point AS7e and the point AS8e. The length WS that is derived from the straight line LN4b is about 12 percent less than the length WS derived from the straight line LN4.

As described above, it is preferred that the relationship in the piezoelectric vibrating piece between the length WS and the length WA be as follows. The length WS is less than 112% and more than 88% of the length WS derived from the straight line LN4. That is, it is preferred that the relationship in the piezoelectric vibrating piece between the length WS and the length WA satisfy equation 8 below.

(0.7237×WA−0.272)×0.88<WS<(0.7237×WA−0.272)×1.12 Equation (8)

### Second Embodiment

The piezoelectric vibrating piece may have a connecting portion with the same thickness as that of the peripheral region in the vibrator. A piezoelectric vibrating piece 230 that has the connecting portion with the same thickness as that of the peripheral region in the vibrator will be described below. In the following description, like reference numerals designate corresponding or identical elements of the piezoelectric vibrating piece in the first embodiment, and therefore such elements will not be further elaborated here.

### Configuration of the Piezoelectric Vibrating Piece 230

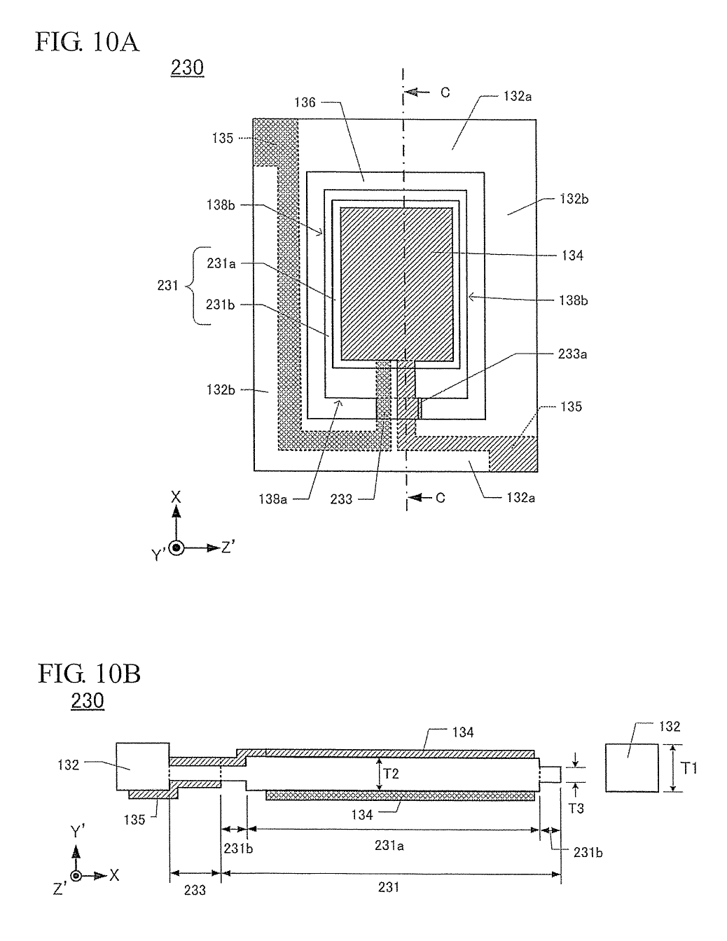

FIG. 10A is a plan view of the piezoelectric vibrating piece 230. The piezoelectric vibrating piece 230 includes a vibrator 231, which vibrates at a predetermined vibration frequency and is formed in a quadrangular shape, the framing portion 132, which surrounds the vibrator 231, and one connecting portion 233, which connects the vibrator 231 and the framing portion 132 together. A region, which is other than the connecting portion 233, between the vibrator 231 and the framing portion 132 forms the through hole 136 passing through the piezoelectric vibrating piece 230 in the Y′ axis direction. The vibrator 231 includes a mesa region 231a with the excitation electrodes 134 and a peripheral region 231b, which is formed around the mesa region 231a and has a smaller thickness in the Y′ axis direction than that of the mesa region 231a. The vibrator 131 has the first side 138a and the second sides 138b. The first side 138a is a short side of the vibrator 131, and is also a side of the vibrator 131 at the −X axis side. The second sides 138b are long sides of the vibrator 131, and are also sides of the vibrator 131 at the +Z′ axis side and the −Z′ axis side. The framing portion 132 includes the first frames 132a, which extends in the Z′ axis direction, and the second frames 132b, which extends in the X axis direction. The connecting portion 233 is connected to the center of the first side 138a in the vibrator 231, extends from this center to the −X axis direction, and is connected to the center of the first frame 132a at the −X axis side. The excitation electrodes 134 in the mesa region 231a are formed on the surface at the +Y′ axis side and the surface at the −Y′ axis side in the mesa region 231a. From the excitation electrode 134 on the surface at the +Y′ axis side of the mesa region 231a, an extraction electrode 135 is extracted via the peripheral region 231b, the surface at the +Y′ axis side of the connecting portion 233, a side face 233a at the +Z′ axis side of the connecting portion 233, and the surface at the −Y′ axis side of the connecting portion 233. The extraction electrode 135 is extracted to a corner portion at the −X axis side and the +Z′ axis side on the surface at the −Y′ axis side of the framing portion 132. From the excitation electrode 134 (see FIG. 10B) on the surface at the −Y′ axis side of the mesa region 231a, an extraction electrode 135 is extracted to the framing portion 132 via the peripheral region 231b and the surface at the −Y′ axis side of the connecting portion 233. The extraction electrode 135 further extends to the −Z′ axis direction and then +X axis direction on the surface at the −Y′ axis side of the framing portion 132. Then, the extraction electrode 135 is extracted to a corner portion at the +X axis side and the −Z′ axis side on the surface at the −Y′ axis side of the framing portion 132. The extraction electrode 135, which is extracted from the excitation electrode 134 on the surface at the −Y′ axis side, is extracted to the +X axis side of the framing portion 132. Thus, the extraction electrode 135 has a longer formation distance than that of the extraction electrode 135 extracted from the excitation electrode 134 on the surface at the +Y′ axis side.

FIG. 10B is a cross-sectional view taken along the line C-C of FIG. 10A. Assume that the piezoelectric vibrating piece 230 has a thickness T1 of the framing portion 132 in the Y′ axis direction, a thickness T2 of the mesa region 231a in the Y′ axis direction, and thicknesses T3 of the connecting portion 233 and the peripheral region 231b of the vibrator 231 in the Y′ axis direction. That is, the connecting portion 233 and the peripheral region 231b are directly connected together with the thickness T3. In the piezoelectric vibrating piece 230, the thickness T1 is thicker than the thickness T2 and the thickness T3, while the thickness T2 is thicker than the thickness T3.

### Configuration of a Piezoelectric Device 500 According to a Third Embodiment

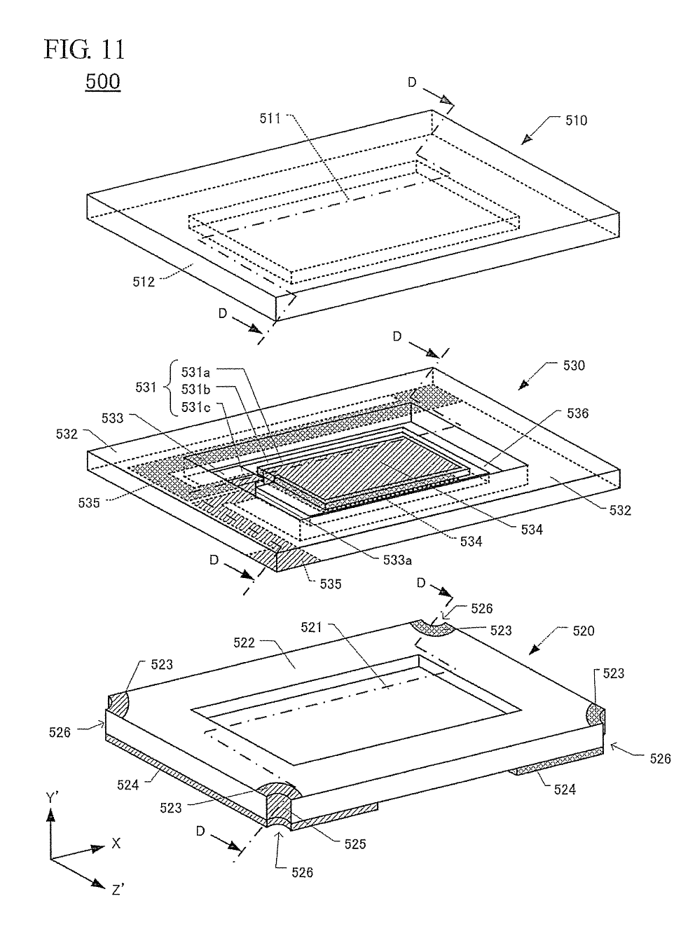

FIG. 11 is an exploded perspective view of the piezoelectric device 500. The piezoelectric device 500 includes a lid plate 510, a base plate 520, and a piezoelectric vibrating piece 530. The piezoelectric vibrating piece 530 employs, for example, an AT-cut quartz-crystal vibrating piece. The AT-cut quartz-crystal vibrating piece has a principal surface (in the Y-Z plane) that is tilted by 35° 15′ about the Y-axis of the crystal coordinate system (XYZ) in the direction from the Z-axis to the Y-axis around the X-axis. In the following description, the new axises tilted with reference to the axis directions of the AT-cut quartz-crystal vibrating piece are denoted as the Y′ axis and the Z′ axis. Therefore, in the piezoelectric device 500, the longitudinal direction of the piezoelectric device 500 is referred as the X axis direction, the height direction of the piezoelectric device 500 is referred as the Y′ axis direction, and the direction perpendicular to the X axis and the Y′ axis directions is referred to as the Z′ axis direction.

The piezoelectric vibrating piece 530 includes a vibrator 531, which vibrates at a predetermined vibration frequency, a framing portion 532, which surrounds the vibrator 531, and a connecting portion 533, which connects the framing portion 532 and the vibrator 531 together. The vibrator 531 includes excitation electrodes 534 on surfaces at the +Y′ axis side and the −Y′ axis side of the vibrator 531. From the excitation electrodes 534, respective extraction electrodes 535 are extracted via the connecting portion 533 to the framing portion 532.

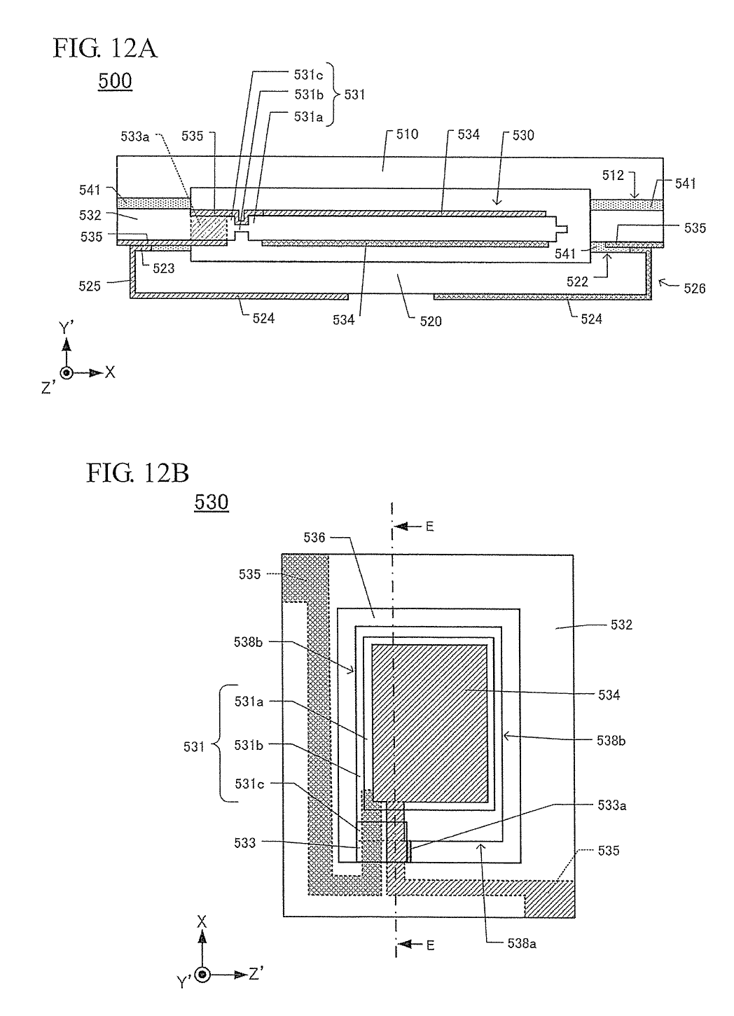

The base plate 520 is disposed at the −Y′ axis side of the piezoelectric vibrating piece 530. The base plate 520 is formed in a rectangular shape that has long sides in the X axis direction and short sides in the Z′ axis direction. The base plate 520 includes a pair of external electrodes 524 on its surface at the −Y′ axis side. The external electrodes 524 are secured and electrically connected to a printed circuit board or the like via solder (not shown). This mounts the piezoelectric device 500 on the printed circuit board or the like. On side faces at four corners of the base plate 520, castellations 526 are formed, while castellation electrodes 525 are formed on the castellations 526. The base plate 520 includes a recess 521 on its surface at the +Y′ axis side. A bonding surface 522 is formed in a peripheral area of the recess 521. Coupling electrodes 523 are formed in peripheral areas of the castellations 526 at the four corners of the bonding surface 522. The coupling electrodes 523 are electrically connected to the external electrodes 524 via the castellation electrodes 525 on the castellation 526. The base plate 520 is bonded to the surface at the −Y′ axis side of the framing portion 532 in the piezoelectric vibrating piece 530 via a sealing material 541 (see FIGS. 12A and 12B) on the bonding surface 522. The coupling electrodes 523 are electrically connected to the extraction electrodes 535 of the piezoelectric vibrating piece 530.

The lid plate 510 is disposed at the +Y′ axis side of the piezoelectric vibrating piece 530. The lid plate 510 includes a recess 511 on its surface at the −Y′ axis side. A bonding surface 512 is formed in a peripheral area of the recess 511. The lid plate 510 is bonded to the surface at the +Y′ axis side of the framing portion 532 in the piezoelectric vibrating piece 530 via the sealing material 541 (see FIGS. 12A and 12B) on the bonding surface 512.

FIG. 12A is a cross-sectional view taken along the line D-D of FIG. 11. The piezoelectric device 500 includes the piezoelectric vibrating piece 530 with the framing portion 532. The framing portion 532 has the surface at the +Y′ axis side, which is bonded to the bonding surface 512 of the lid plate 510 via the sealing material 541. The framing portion 532 has the surface at the −Y′ axis side, which is bonded to the bonding surface 522 of the base plate 520 via the sealing material 541. When the piezoelectric vibrating piece 530 and the base plate 520 are bonded together, the extraction electrodes 535, which are formed on the surface of the framing portion 532 at the −Y′ axis side, and the coupling electrodes 523, which are formed on the bonding surface 522 of the base plate 520, are electrically connected to one another. Accordingly, respective excitation electrodes 534, which are formed at the +Y′ axis side and the −Y′ axis side of the vibrator 531, are electrically connected to the external electrodes 524 via the extraction electrode 535, the coupling electrode 523, and the castellation electrode 525.

FIG. 12B is a plan view of the piezoelectric vibrating piece 530. The piezoelectric vibrating piece 530 includes the vibrator 531 in a rectangular shape, the framing portion 532, which surrounds the vibrator 531, the one connecting portion 533, which connects the vibrator 531 and the framing portion 532 together. The vibrator 531 includes a first side 538a, which is the side of the vibrator 531 at the −X axis side, and second sides 538b, which are sides of the vibrator 531 at the +Z′ axis side and the −Z′ axis side. The connecting portion 533 is an end portion at the −Z′ axis side of the first side 538a in the vibrator 531, and connected at a portion that includes a corner portion where the first side 538a and the second side 538b intersect with one another. Then, the connecting portion 533 extends from the connected portion to the −X axis direction, and is connected to the framing portion 532. A region, which is other than the connecting portion 533, between the vibrator 531 and the framing portion 532 forms a void 536 that passes through the piezoelectric vibrating piece 530 in the Y′ axis direction. The vibrator 531 includes the mesa region 531a with the excitation electrodes 534, a peripheral region 531b around the mesa region 531a, and a connecting region 531c, which is directly connected to the connecting portion 533. The peripheral region 531b is formed between the mesa region 531a and the connecting region 531c while the mesa region 531a and the connecting region 531c do not contact one another. From the excitation electrode 534 on the surface at the +Y′ axis side of the mesa region 531a, an extraction electrode 535 is extracted via the peripheral region 531b, the connecting region 531c, the surface at the +Y′ axis side of the connecting portion 533, a side face 533a at the +Z′ axis side of the connecting portion 533, and the surface at the −Y′ axis side of the connecting portion 533. The extraction electrode 535 is extracted to a corner portion at the −X axis side and the +Z′ axis side on the surface at the −Y′ axis side of the framing portion 532. From the excitation electrode 534 (see FIG. 12A) on the surface at the −Y′ axis side of the mesa region 531a, an extraction electrode 535 is extracted to the framing portion 532 via the peripheral region 531b, the connecting region 531c, and the surface at the −Y′ axis side of the connecting portion 533. The extraction electrode 535 further extends to the −Z′ axis direction and the +X axis direction on the surface at the −Y′ axis side of the framing portion 532, and is extracted to a corner portion at the +X axis side and the −Z′ axis side on the surface at the −Y′ axis side of the framing portion 532. In the piezoelectric vibrating piece 530, the extraction electrode 535 that is extracted from the excitation electrode 534 on the surface at the −Y′ axis side is extracted to the +X axis side of the framing portion 532. Thus, this extraction electrode 535 has a longer formation distance than that of the extraction electrode 535 that is extracted from the excitation electrode 534 on the surface at the +Y′ axis side.

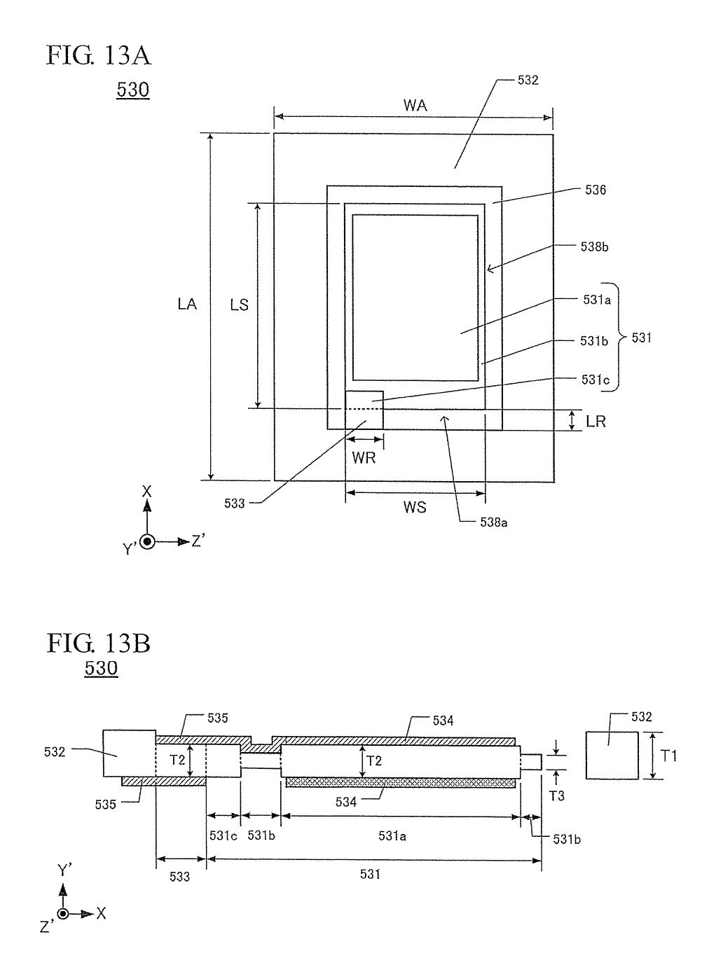

FIG. 13A is a plan view of the piezoelectric vibrating piece 530 without electrodes. The vibrator 531 has the first side 538a with a length WS and the second side 538b with a length LS. Assume that in the piezoelectric vibrating piece 530, the whole framing portion 532 has a length WA in the Z′ axis direction, the whole framing portion 532 has a length LA in the X axis direction, the connecting portion 533 has a width WR in the Z′ axis direction, and the connecting portion 533 has a length LR in the X axis direction.

FIG. 13B is a cross-sectional view taken along the line E-E of FIG. 12B. Assume that in the piezoelectric vibrating piece 530, the framing portion 532 has a thickness T1 in the Y′ axis direction, the connecting portion 533, the connecting region 531c of the vibrator 531, and the mesa region 531a each have a thickness T2 in the Y′ axis direction, and the peripheral region 531b of the vibrator 531 has a thickness T3 in the Y′ axis direction. That is, the connecting portion 533 and the connecting region 531c are directly connected together with the thickness T2. In the piezoelectric vibrating piece 530, the thickness T1 is thicker than the thickness T2 and the thickness T3, while the thickness T2 is thicker than the thickness T3.

### Simulation Results

In a state where the piezoelectric devices were mounted on printed circuit boards, simulations were carried out to calculate stresses on the piezoelectric vibrating pieces when the printed circuit boards were bent. In the simulations, dimensions of the piezoelectric vibrating pieces were each assumed to have the length LA of 2.0 mm, the length WA of 1.6 mm, the length LS of 1.4 mm, the length WS of 0.99 mm, and the length LR of 0.15 mm. The simulations examined difference of stresses on the piezoelectric vibrating pieces in the case where the width WR of the connecting portion 533 is changed. Simulations were performed in the four cases of the width WR of 0.32 mm, 0.35 mm, 0.45 mm, and 0.55 mm in the connecting portion 533. The simulation results of the piezoelectric vibrating pieces will be described below. The following simulations had been demonstrated that their results were close to actual stress distribution.

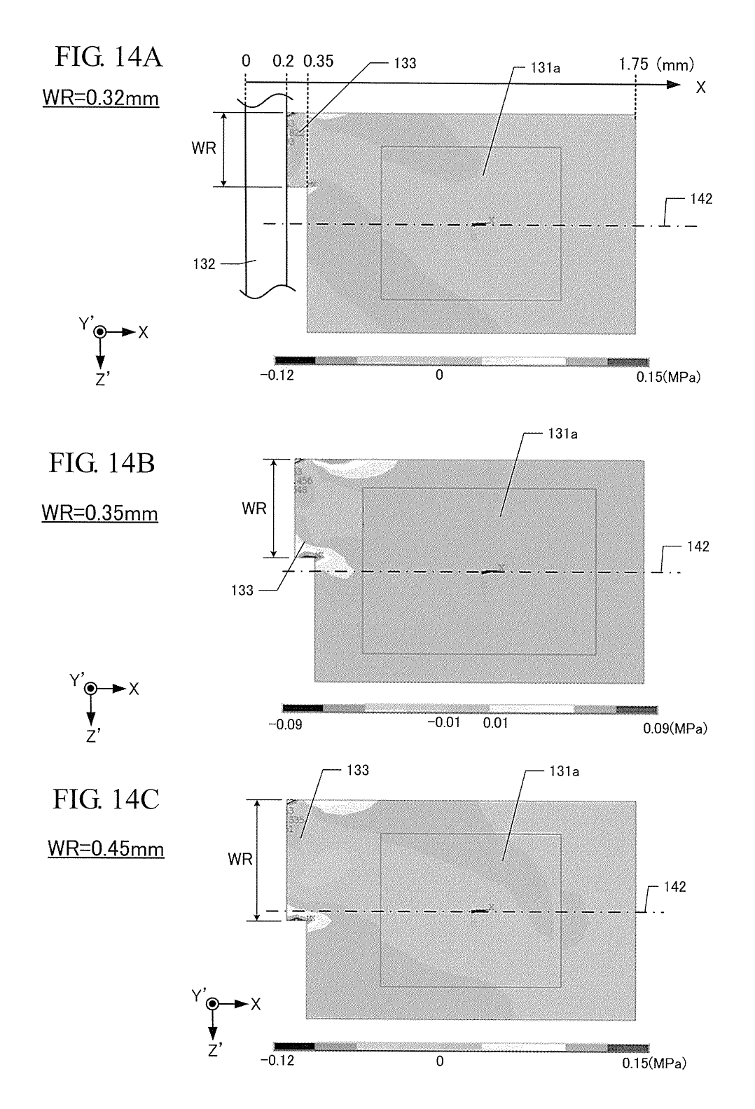

FIG. 14A is a simulation result of the piezoelectric vibrating piece that includes a connecting portion 533 with a width WR of 0.32 mm. FIG. 14A illustrates a simulation result in the plan view of the vibrator 531 and the connecting portion 533. The simulation result shows intensity of stress generated in the X axis direction. A gray region shows a region where approximately no stress in the X axis direction is applied to the piezoelectric vibrating piece. The simulation result also shows tensile stress or compressive stress, which becomes stronger as the color becomes darker from the gray to black, in the X axis direction in the piezoelectric vibrating piece. Similarly, FIGS. 14B to 14C below illustrate intensity of stress generated in the X axis direction. In the piezoelectric vibrating piece of FIG. 14A, the vibrator 531 and the connecting portion 533 are wholly illustrated in the gray. This shows that low stresses are generated in the X axis direction on the vibrator 531 and the connecting portion 533.

FIG. 14B is a simulation result of the piezoelectric vibrating piece that includes a connecting portion 533 with a width WR of 0.35 mm. In the piezoelectric vibrating piece of FIG. 14B, there are regions with darker colors than the gray on side faces at the +Z′ axis side and the −Z′ axis side of the connecting portion 533. Accordingly, generation of stress in the X axis direction were observed. In contrast, the mesa region 531a is in the gray in almost the whole region. This shows almost no stress in the X axis direction is applied to the mesa region 531a.

FIG. 14C is a simulation result of the piezoelectric vibrating piece that includes a connecting portion 533 with a width WR of 0.45 mm. In the piezoelectric vibrating piece of FIG. 14C, regions with darker colors than the gray are observed on side faces at the +Z′ axis side and the −Z′ axis side of connecting portion 533. This shows that stresses in the X axis direction are applied to these regions. In contrast, the mesa region 531a is in the gray in almost the whole region. This shows that almost no stress is applied to the mesa region 531a.

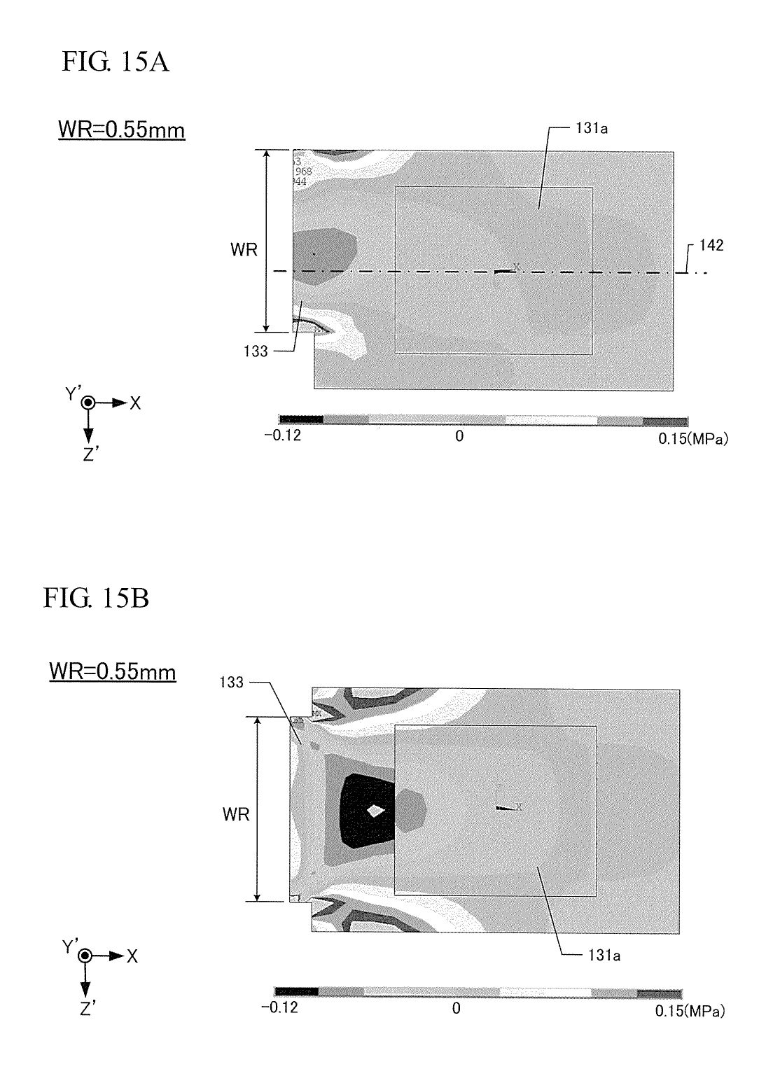

FIG. 15A is a simulation result of the piezoelectric vibrating piece that includes a connecting portion 533 with a width WR of 0.55 mm. In the piezoelectric vibrating piece of FIG. 15A, regions with darker colors than the gray are observed on the side faces at the +Z′ axis side and the −Z′ axis side of the connecting portion 533, and also observed in the center of connecting portion 533 and its vicinity. This shows that stresses in the X axis direction are applied to these regions. In contrast, the mesa region 531a is in the gray in almost the whole region. This shows that almost no stress is applied to the mesa region 531a.

FIG. 15B is a simulation result of the piezoelectric vibrating piece where the connecting portion is connected to the center of the first side in the vibrator. FIG. 15B is shown to compare this piezoelectric vibrating piece with the piezoelectric vibrating piece in FIG. 15A. The piezoelectric vibrating piece in FIG. 15B has the same configuration as that of the piezoelectric vibrating piece in FIG. 15A except that the connecting portion is connected to the center of the first side. In the piezoelectric vibrating piece of FIG. 15B, a black region that has a color darker than the gray is observed between the connecting portion 533 and the mesa region 531a of the vibrator. This shows that a large stress is generated in this region. This black region partially covers the mesa region 531a. Thus, stress is also generated in the mesa region 531a.

Comparing FIGS. 14A, 14B, 14C, and 15A with one another shows more intense stress in the X axis direction on the side faces of the connecting portion 533 and the center region of the connecting portion 533 as the width WR of the connecting portion 533 becomes longer. In the piezoelectric vibrating piece with the width WR of 0.55 mm in FIG. 15A, though the stress on the mesa region 531a that generates vibration of the piezoelectric vibrating piece is not strong, a range of the stress that is generated in the connecting portion 533 is expanded. A larger width WR would causes stress on the mesa region 531a. Accordingly, it is preferred that the width WR of the connecting portion 533 be narrower than 0.55 mm. The width WR of 0.55 mm is 55.6% of the length WS in the piezoelectric vibrating piece. That is, the width WR is preferred to be less than 55.6% of the length WS.

The piezoelectric vibrating piece, where the connecting portion is connected to the end portion of the first side, in FIG. 15A is compared with the piezoelectric vibrating piece, where the connecting portion is connected to the center of the first side, in FIG. 15B. This comparison shows that a larger stress is generated on the piezoelectric vibrating piece in FIG. 15B, compared with the piezoelectric vibrating piece in FIG. 15A. This shows that a larger stress is also generated on the mesa region 531a, compared with the piezoelectric vibrating piece in FIG. 15A. Accordingly, the piezoelectric vibrating piece where the connecting portion is connected to the end portion of the first side is subjected to a smaller stress compared with the piezoelectric vibrating piece where the connecting portion is connected to the center of the first side. Since a stress on the mesa region is also small, change in characteristic of vibration frequency is small regarding the vibrator of the piezoelectric vibrating piece.

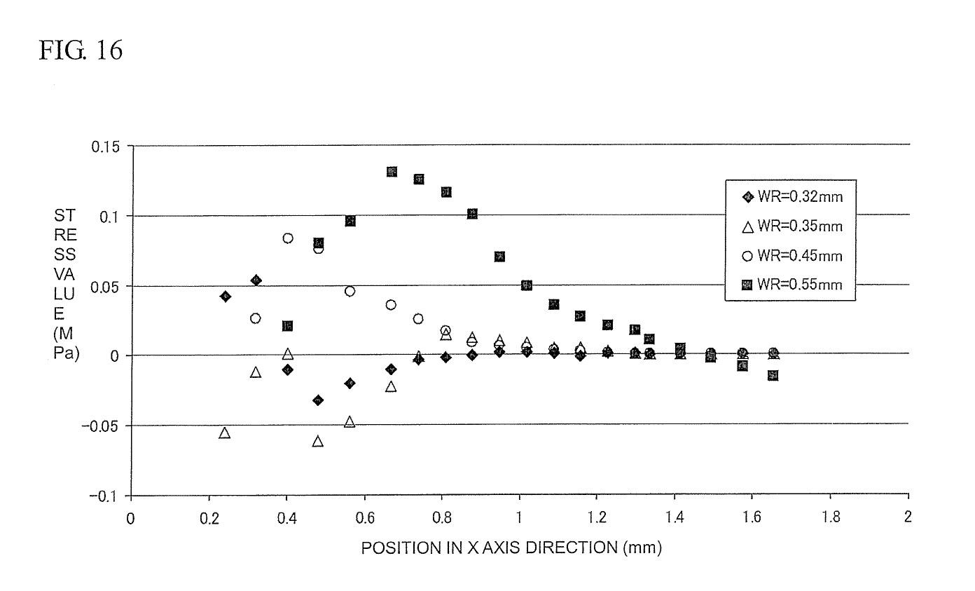

FIG. 16 is a graph illustrating a distribution of stress value in the Z′ axis direction applied to the piezoelectric vibrating piece where the connecting portion 533 is connected to the end portion of the first side 538a. The horizontal axis shows positions on the straight line 542 (see FIGS. 14A to 14C, and 15A), which passes through the center of the connecting portion 533 in the piezoelectric vibrating piece and is parallel to the X axis. Further, the horizontal axis will be described by referring to FIG. 14A. The horizontal axis in FIG. 16 illustrates positions in the +X axis direction from the end, which is assumed to be 0 mm, at the −X axis side of the framing portion 532 at the −X axis side. The vertical axis in FIG. 16 illustrates values of stress in the Z′ axis direction applied to the piezoelectric vibrating piece. Regarding these stress values, positive values indicate tensile stress, while negative values indicate compressive stress. In FIG. 16, black diamonds indicate the piezoelectric vibrating piece with the width WR of 0.32 mm, white triangles indicate the piezoelectric vibrating piece with the width WR of 0.35 mm, white circles indicate the piezoelectric vibrating piece with the width WR of 0.45 mm, and black squares indicate the piezoelectric vibrating piece with the width WR of 0.55 mm.

In FIG. 16, a position in the X axis direction that is equal to or more than 0.35 mm indicates a position of the vibrator 531 (see FIG. 14A). Accordingly, the maximum absolute value of the stress values in a range of positions equal to or more than 0.35 mm in the X axis direction is examined so as to examine stress on the vibrator 531. The piezoelectric vibrating piece with the width WR of 0.55 mm takes about 0.13 MPa as the maximum absolute value of the stress value when the position becomes 0.67 mm in the X axis direction. The piezoelectric vibrating piece with the width WR of 0.45 mm takes about 0.08 MPa as the maximum absolute value of the stress value when the position becomes 0.40 mm in the X axis direction. The piezoelectric vibrating piece with the width WR of 0.35 mm takes about −0.061 MPa as the maximum absolute value of the stress value when the position becomes 0.48 mm in the X axis direction. The piezoelectric vibrating piece with the width WR of 0.32 mm takes about −0.033 MPa as the maximum absolute value of the stress value when the position becomes 0.48 mm in the X axis direction.

The absolute value of the stress value regarding stress on the vibrator 531 is preferred to be below 0.1 MPa considering change in vibration frequency of the piezoelectric vibrating piece. According to FIG. 16, in the piezoelectric vibrating piece with the width WR of 0.55 mm, the maximum value of stress on the piezoelectric vibrating piece exceeds 0.1 MPa. In contrast, the piezoelectric vibrating pieces with the widths WR of 0.45 mm, 0.35 mm, and 0.32 mm each have a preferred absolute value of the maximum stress value below 0.1 MPa on the piezoelectric vibrating pieces. On the other hand, in the case where the width WR is smaller than 0.28 mm, impact resistance of the piezoelectric vibrating piece becomes low. This causes a damage of the piezoelectric vibrating piece in a drop test of the piezoelectric device as demonstrated by the experiments. Accordingly, it is preferred that the width WR of the connecting portion 533 be larger than 0.28 mm and smaller than 0.45 mm. These values correspond to values of the width WS of the first side from about 28% to about 46%. That is, the width WR is preferred to be from 28% to 46% of the width WS.

### Fourth Embodiment

The piezoelectric vibrating piece may have a connecting portion with the same thickness as that of the peripheral region in the vibrator. The connecting portion may also be connected to the long side of the vibrator. A piezoelectric vibrating piece 630 that has the connecting portion with the same thickness as that of the peripheral region in the vibrator, and a piezoelectric vibrating piece 730 that has the connecting portion connected to the long side of the vibrator will be described below. In the following description, like reference numerals designate corresponding or identical elements of the piezoelectric vibrating piece in the first embodiment, and therefore such elements will not be further elaborated here.

### Configuration of the Piezoelectric Vibrating Piece 630

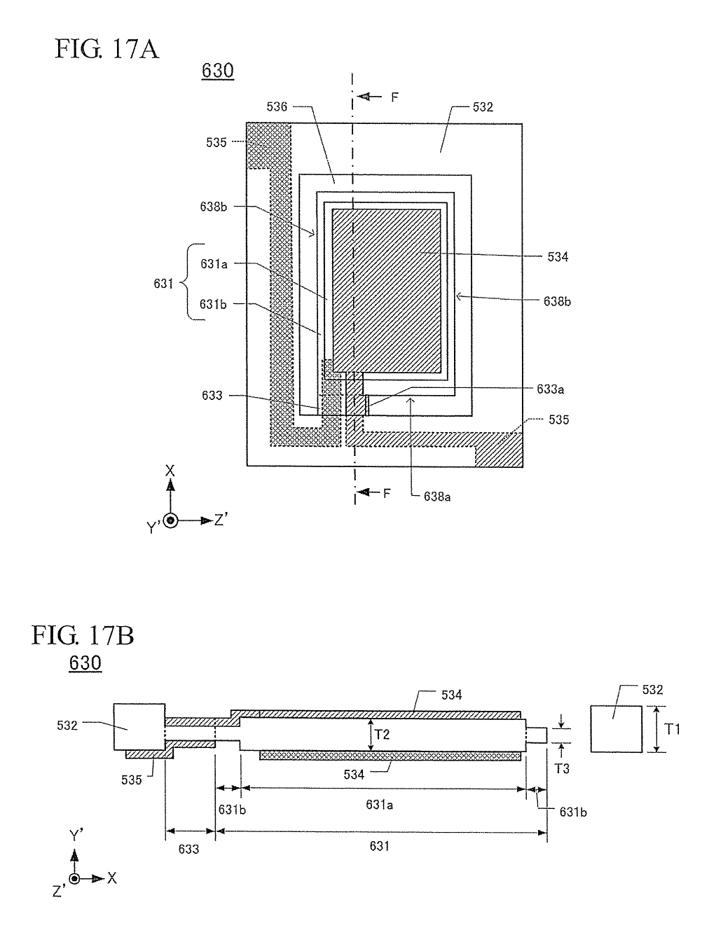

FIG. 17A is a plan view of the piezoelectric vibrating piece 630. The piezoelectric vibrating piece 630 includes a vibrator 631, which vibrates at a predetermined vibration frequency and is in a quadrangular shape, the framing portion 532, which surrounds the vibrator 631, and one connecting portion 633, which connects the vibrator 631 and the framing portion 532 together. A region, which is other than the connecting portion 633, between the vibrator 631 and the framing portion 532 forms the void 536 that passes through the piezoelectric vibrating piece 630 in the Y′ axis direction. The vibrator 631 includes a mesa region 631a with the excitation electrodes 534 and a peripheral region 631b, which is formed around the mesa region 631a and has a smaller thickness in the Y′ axis direction than that of the mesa region 631a.

The vibrator 631 has a first side 638a and a second sides 638b. The first side 638a is a short side of the vibrator 631, and also the side of the vibrator 631 at the −X axis side. The second sides 638b are long sides of the vibrator 631, and also the respective sides of the vibrator 631 at the +Z′ axis side and the −Z′ axis side. The connecting portion 633 is connected to an end portion at the −Z′ axis side of the first side 638a in the vibrator 631 and extends from this end portion to the −X axis direction, thus connecting to the framing portion 532. The excitation electrodes 534 in the mesa region 631a are formed on the surface at the +Y′ axis side and the surface at the −Y′ axis side in the mesa region 631a. From the excitation electrode 534 on the surface at the +Y′ axis side of the mesa region 631a, an extraction electrode 535 is extracted via the peripheral region 631b, the surface at the +Y′ axis side of the connecting portion 633, a side face 633a at the +Z′ axis side of the connecting portion 633, and the surface at the −Y′ axis side of the connecting portion 633. The extraction electrode 535 is extracted to a corner portion at the −X axis side and the +Z′ axis side on the surface at the −Y′ axis side of the framing portion 532. From the excitation electrode 534 (see FIG. 17B) on the surface at the −Y′ axis side of the mesa region 631a, an extraction electrode 535 is extracted to the framing portion 532 via the peripheral region 631b and the surface at the −Y′ axis side of the connecting portion 633. The extraction electrode 535 extends to the −Z′ axis direction and then +X axis direction on the surface at the −Y′ axis side of the framing portion 532 and is extracted to a corner portion at the +X axis side and the −Z′ axis side on the surface at the −Y′ axis side of the framing portion 532. The extraction electrode 535 that is extracted from the excitation electrode 534 on the surface at the −Y′ axis side is extracted to the +X axis side of the framing portion 532. Thus, this extraction electrode 535 has a longer formation distance than that of the extraction electrode 535 extracted from the excitation electrode 534 on the surface at the +Y′ axis side.

FIG. 17B is a cross-sectional view taken along the line F-F of FIG. 17A. Assume that in the piezoelectric vibrating piece 630, the framing portion 532 has the thickness T1 in the Y′ axis direction, the mesa region 631a has the thickness T2 in the Y′ axis direction, and the connecting portion 633 and the vibrator 631 of the peripheral region 631b each have the thickness T3 in the Y′ axis direction. That is, the connecting portion 633 and the peripheral region 631b are directly connected together with the thickness T3. In the piezoelectric vibrating piece 630, the thickness T1 is thicker than the thickness T2 and the thickness T3, while the thickness T2 is thicker than the thickness T3.

As shown in the piezoelectric vibrating piece 630, a result of the piezoelectric vibrating piece where the connecting portion 633 has the same thickness as that of the peripheral region 631b is obtained, similarly to the piezoelectric vibrating piece 530. That is, the piezoelectric vibrating piece 630 is preferred to have the width WR that is from 28% to 46% of the length WS.

### Configuration of a Piezoelectric Vibrating Piece 730

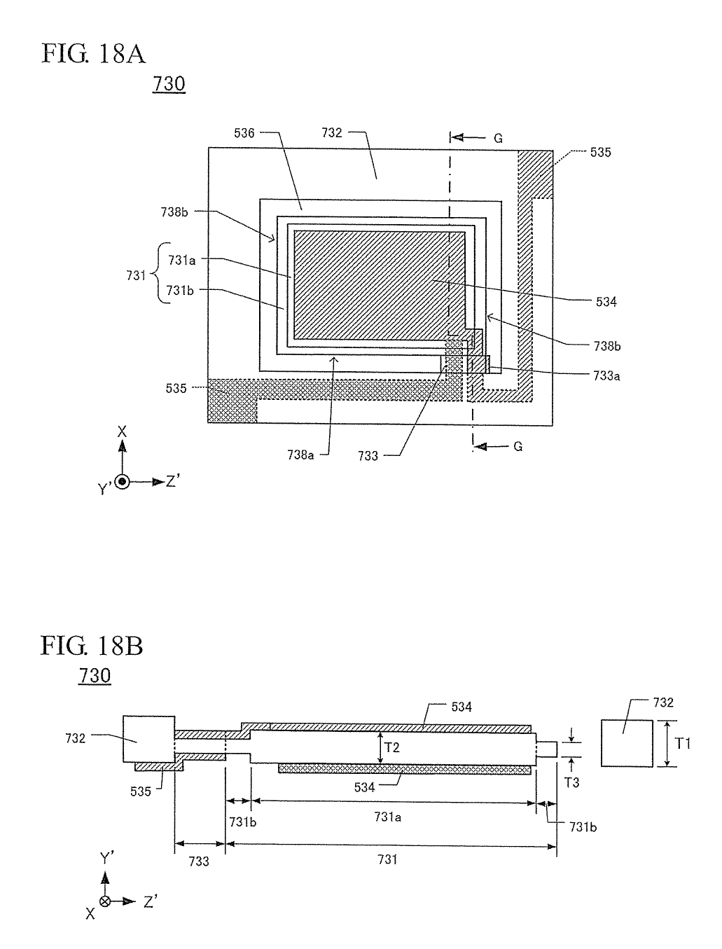

FIG. 18A is a plan view of the piezoelectric vibrating piece 730. The piezoelectric vibrating piece 730 includes a vibrator 731, the framing portion 732, and one connecting portion 733. The vibrator 731 in a quadrangular shape vibrates at a predetermined vibration frequency. The framing portion 732 surrounds the vibrator 731. The one connecting portion 733 connects the vibrator 731 and the framing portion 732 together. A region, which is other than the connecting portion 733, between the vibrator 731 and the framing portion 732 forms the void 536 that passes through the piezoelectric vibrating piece 730 in the Y′ axis direction. The vibrator 731 includes a mesa region 731a with the excitation electrodes 534 and a peripheral region 731b, which is formed around the mesa region 731a, and has a smaller thickness in the Y′ axis direction than that of the mesa region 731a.

The vibrator 731 has a first side 738a and second sides 738b. The first side 738a is a short side of the vibrator 731, and also the side of the vibrator 731 at the −X axis side. The second sides 738b are long sides of the vibrator 731, and also the respective sides of the vibrator 731 at the +Z′ axis side and the −Z′ axis side. The connecting portion 733 is connected to an end portion at the +Z′ axis side of the first side 738a in the vibrator 731 and extends from this end portion to the −X axis direction, and is connected to the framing portion 732. The excitation electrodes 534 in the mesa region 731a are formed on the surface at the +Y′ axis side and the surface at the −Y′ axis side in the mesa region 731a. From the excitation electrode 534 on the surface at the +Y′ axis side of the mesa region 731a, an extraction electrode 535 is extracted via the peripheral region 731b, the surface at the +Y′ axis side of the connecting portion 733, the side face 733a at the +Z′ axis side of the connecting portion 733, and the surface at the −Y′ axis side of the connecting portion 733. The extraction electrode 535 is extracted to a corner portion at the +X axis side and the +Z′ axis side on the surface at the −Y′ axis side of the framing portion 732. From the excitation electrode 534 (see FIG. 18B) on the surface at the −Y′ axis side of the mesa region 731a, an extraction electrode 535 is extracted to the framing portion 732 via the peripheral region 731b and the surface at the −Y′ axis side of the connecting portion 733. The extraction electrode 535 extends to the −Z′ axis direction on the surface at the −Y′ axis side of the framing portion 732 and is extracted to a corner portion at the −X axis side and the −Z′ axis side on the surface at the −Y′ axis side of the framing portion 732.

FIG. 18B is a cross-sectional view taken along the line G-G of FIG. 18A. Assume that in the piezoelectric vibrating piece 730, the framing portion 732 has the thickness T1 in the Y′ axis direction, the mesa region 731a has the thickness T2 in the Y′ axis direction, and the connecting portion 733 and the vibrator 731 of the peripheral region 731b each have the thickness T3 in the Y′ axis direction. That is, the connecting portion 733 and the peripheral region 731b are directly connected together with the thickness T3. In the piezoelectric vibrating piece 730, the thickness T1 is thicker than the thickness T2 and the thickness T3, while the thickness T2 is thicker than the thickness T3.

A comparison between FIG. 15A and FIG. 15B shows that stress on the mesa region where the connecting portion is formed in the end portion of the first side is lower than stress on the mesa region where the connecting portion is formed in the center of the first side. This result applies to the piezoelectric vibrating piece 730, which has the first side longer than the second side.

Representative embodiments have been described in detail above. As evident to those skilled in the art, the present invention may be changed or modified in various ways within the technical scope of the invention.

For example, while in the embodiments, the piezoelectric vibrating pieces are AT-cut quartz-crystal vibrating pieces, for example, a BT-cut, which vibrates in a thickness-shear vibration mode, or tuning-fork type quartz-crystal vibrating piece may also be used, similarly to the AT-cut quartz-crystal vibrating pieces. Further, the piezoelectric vibrating pieces are basically applied to piezoelectric material including not only quartz-crystal material but also lithium tantalite, lithium niobate, and piezoelectric ceramic.

In the first and second embodiments, configuration examples where the connecting portion is connected to the center of the first side in the vibrator are disclosed. However, the first and second embodiments are not limited to the configurations where the connecting portion is connected to the center of the first side in the vibrator. Specifically the connecting portion of the first and second embodiments may be connected to the end portion of the first side in the vibrator, similarly to the third and fourth embodiments, for example.

What is claimed is:

1. A piezoelectric vibrating piece comprising:
a vibrator in a rectangular shape, the vibrator including a first side and a pair of second sides, the first side extending in a first direction, the second sides extending in a second direction perpendicular to the first direction;
a framing portion that surrounds the vibrator across a void; and
one connecting portion that connects the first side of the vibrator and the framing portion together, the one connecting portion having a predetermined width in the first direction, the one connecting portion extending in the second direction.

2. The piezoelectric vibrating piece according to claim 1, wherein,
the first side has a length WS and extends in the first direction,
the second side has a length LS and extends in the second direction,
the framing portion includes a first frame with a length WA and a second frame with a length LA, the first frame extending in the first direction, the second frame extending in the second direction, the framing portion surrounding the vibrator with the first frame and the second frame,
the one connecting portion connects the first side of the vibrator and the first frame of the framing portion one another, the one connecting portion having a width WR in the first direction and a length LR in the second direction, and
the piezoelectric vibrating piece satisfies at least one of following equations (1) to (4):
(0.1471×LS−0.004)×0.75<LR<(0.1471×LS−0.004)×1.25 (1);
(0.3545×WS+0.044)×0.8<WR<(0.3545×WS+0.044)×1.2 (2);
(0.85×LA−0.3125)×0.94<LS<(0.85×LA−0.3125)×1.06 (3); and
(0.7237×WA−0.272)×0.88<WS<(0.7237×WA−0.272)×1.12 (4).

3. The piezoelectric vibrating piece according to claim 2, wherein,
the one connecting portion connects the first side of the vibrator and the first frame of the framing portion one another at respective centers of the first side and the first frame.

4. The piezoelectric vibrating piece according to claim 1, wherein,
the one connecting portion extends from a corner portion where the first side and the second side intersect with one another.

5. The piezoelectric vibrating piece according to claim 4, wherein,
the first side has a shorter length than a length of the second side, and
the predetermined width is from 28% to 46% of a length of the first side.

6. The piezoelectric vibrating piece according to claim 4, wherein,
the first side has a longer length than a length of the second side.

7. The piezoelectric vibrating piece according to claim 2, wherein,
the vibrator includes a mesa region and a peripheral region around the mesa region, the peripheral region having a thickness smaller than a thickness of the mesa region,
the mesa region includes an excitation electrode, and
the connecting portion and the framing portion include an extraction electrode, the extraction electrode being extracted from the excitation electrode.

8. The piezoelectric vibrating piece according to claim 3, wherein,
the vibrator includes a mesa region and a peripheral region around the mesa region, the peripheral region having a thickness smaller than a thickness of the mesa region,
the mesa region includes an excitation electrode, and
the connecting portion and the framing portion include an extraction electrode, the extraction electrode being extracted from the excitation electrode.

9. The piezoelectric vibrating piece according to claim 4, wherein,
the vibrator includes a mesa region and a peripheral region around the mesa region, the peripheral region having a thickness smaller than a thickness of the mesa region,
the mesa region includes an excitation electrode, and
the connecting portion and the framing portion include an extraction electrode, the extraction electrode being extracted from the excitation electrode.

10. The piezoelectric vibrating piece according to claim 5, wherein,
the vibrator includes a mesa region and a peripheral region around the mesa region, the peripheral region having a thickness smaller than a thickness of the mesa region,
the mesa region includes an excitation electrode, and
the connecting portion and the framing portion include an extraction electrode, the extraction electrode being extracted from the excitation electrode.

11. The piezoelectric vibrating piece according to claim 6, wherein,
the vibrator includes a mesa region and a peripheral region around the mesa region, the peripheral region having a thickness smaller than a thickness of the mesa region,
the mesa region includes an excitation electrode, and
the connecting portion and the framing portion include an extraction electrode, the extraction electrode being extracted from the excitation electrode.

12. The piezoelectric vibrating piece according to claim 2, wherein,
the connecting portion has a thickness, the thickness being a same as a thicknesses of the peripheral region of the vibrator.

13. The piezoelectric vibrating piece according to claim 3, wherein,
the connecting portion has a thickness, the thickness being a same as a thicknesses of the peripheral region of the vibrator.

14. The piezoelectric vibrating piece according to claim 4, wherein,
the connecting portion has a thickness, the thickness being a same as one of thicknesses of the peripheral region of the vibrator and the mesa region.

15. The piezoelectric vibrating piece according to claim 5, wherein,
the connecting portion has a thickness, the thickness being a same as one of thicknesses of the peripheral region of the vibrator and the mesa region.

16. The piezoelectric vibrating piece according to claim 6, wherein,
the connecting portion has a thickness, the thickness being a same as one of thicknesses of the peripheral region of the vibrator and the mesa region.

17. A piezoelectric device comprising:
the piezoelectric vibrating piece according to claim 1;
a lid plate bonded to one main surface of the framing portion; and
a base plate bonded to another main surface of the framing portion.
